(19) United States
(12) Patent Application Publication
(10) Pub. No.: US 2018/0314098 A1
(43) Pub. Date: Nov. 1, 2018

(54) DISPLAY BOARD AND DISPLAY DEVICE

(71) Applicant: SHARP KABUSHIKI KAISHA, Sakai City, Osaka (JP)

(72) Inventors: TAKAO SAITOH, Sakai City (JP); YOHSUKE KANZAKI, Sakai City (JP); MAKOTO NAKAZAWA, Sakai City (JP); KAZUATSU ITO, Sakai City (JP); SEIJI KANEKO, Sakai City (JP)

(73) Assignee: SHARP KABUSHIKI KAISHA, Sakai City, Osaka (JP)

(21) Appl. No.: 15/772,085

(22) PCT Filed: Nov. 1, 2016
(86) PCT No.: PCT/JP2016/082383

§ 371 Date: Apr. 29, 2018

(30) Foreign Application Priority Data
Nov. 6, 2015 (JP) 2015-218419

(51) Int. Cl. G02F 1/1345; H01L 27/12; G02F 1/1368; G02F 1/1333; G02F 1/1335; G06F 3/041; G02F 1/1362; H05K 1/18; G02F 1/1339; G02F 1/1343

(52) U.S. Cl. CPC G02F 1/13452; G02F 2001/133357; G02F 1/1368; G02F 1/133345; G02F 1/133514; G02F 1/133512; G02F 1/13338; G06F 3/0412; G02F 1/136286; H05K 1/189; G02F 1/1339; G02F 1/134309; G02F 2201/121; G02F 2201/123; H01L 27/124

(57) ABSTRACT

An array board includes a glass substrate, gate insulating film, a first interlayer insulating film, a gate insulating film inclined section, a first interlayer insulating film inclined section, and an overlapping portion. The glass substrate includes a display area and a non-display area. The gate insulating film and the first interlayer insulating film include a gate insulating film voided area and a first interlayer insulating film voided area in the non-display area. The gate insulating film inclined section and the interlayer insulating film inclined section are inclined from boundaries with the gate insulating film voided area and the first interlayer insulating film voided area and angled relative to a plate surface of the glass substrate. The overlapping portion overlaps the gate insulating film voided area, the first interlayer insulating film voided area, the gate insulating film inclined section, and the first interlayer insulating film inclined section.

### TECHNICAL FIELD

The present invention relates to a display board and a display device.

### BACKGROUND ART

A liquid crystal panel disclosed in Patent Document 1 is known as an example of liquid crystal panels used in conventional liquid crystal display devices. The liquid crystal panel disclosed in Patent Document 1 includes an active component array board that includes an interlayer insulating film. The interlayer insulating film includes a protrusion at an interlayer insulating film edge between mounted terminals to reduce resist residues in a post-process even if the interlayer insulating film is formed with a large thickness.

### RELATED ART DOCUMENT

### Patent Document

Patent Document 1: Japanese Unexamined Patent Application Publication No. H11-24101

### Problem to be Solved by the Invention

In the active component array board disclosed in Patent Document 1, an interlayer insulating film edge section of the interlayer insulating film is angled relative to a plate surface of a board to incline upward. According to the configuration, moisture is more likely to remain in an area that crosses a section of the board in which the interlayer insulating film is not disposed and the interlayer insulating film edge section. If the moisture that remains in the area enters the interlayer insulating film or an interface with another film, air bubbles may be formed in a liquid crystal layer resulting in a display failure.

### DISCLOSURE OF THE PRESENT INVENTION

The present invention was made in view of the above circumstances. An object is to reduce display failures resulting from retention of moisture.

### Means for Solving the Problem

A display board according to the present invention includes a board, an insulating film, at least one inclined section, and an overall portion. The board includes a display area in which an image can be displayed and a non-display area disposed outside the display area to surround the display area. The insulating film is disposed to cross a boundary between the display area and the non-display area and includes a hole at least in the non-display area. The hole is defined as an insulating film voided area. The at least one inclined section is inclined from a boundary with the insulating film voided area and angled relative to a plate surface of the board. The at least one inclined section is a section of the insulating film. The overlapping portion is disposed in a layer upper than the insulating film to overlap the insulating film voided area and the at least one inclined section to cross the boundary between the insulating film voided area and the at least one inclined section.

The insulating film is disposed to cross the boundary between the display area and the non-display area and includes the insulating film voided area, which is the hole in the non-display area. The insulating film voided area in which the insulating film does not exist is disposed in the non-display area of the board. Therefore, the insulating film voided area is less likely to affect the image displayed in the display area. The section of the insulating film is the inclined section that is inclined from the boundary with the insulating film voided area and angled relative to the plate surface of the board. Because the inclined section of the insulating film is angled as described above, moisture is more likely to remain in the inclined section and therearound. Due to the moisture, display performance of the display board may decrease. Because the overlapping portion is disposed in the layer upper than the insulating film to cross the boundary between the insulating film voided area and the inclined section to cover at least parts of the insulating film voided area and the inclined section, the moisture is less likely to remain in the inclined section of the insulating film and therearound. Therefore, the display performance of the display board can be maintained at a proper level.

Preferable embodiments of the present invention may have the following configurations.

(1) The overlapping portion may be angled relative to the plate surface of the board with an angle of slope smaller than an angle of slope of the at least one inclined section. According to the configuration, the moisture is less likely to remain in the overlapping portion and therearound.

(2) The display board may include a second insulating film and a second inclined section. The second insulating film may be disposed in a layer upper than the insulating film and include a hole in an area that overlaps the insulating film voided area and the at least one inclined section. The hole may be defined as a second insulating film voided area. The second inclined section may be inclined from a boundary with the second insulating film voided area and angled relative to the plate surface of the board with an angle of slope smaller than the angle of slope of the at least one inclined section. In such a configuration in which the second insulating film is disposed in the layer upper than the insulating film, if the insulating film is patterned using the second insulating film as a mask, the angle of slope of the inclined section becomes larger than the angle of slope of the second inclined section. Therefore, the moisture may remain in the inclined section. Because the overlapping portion at least overlap the insulating film voided area and the inclined section to cross at least the boundary between the insulating film voided area and the inclined section. Therefore, the moisture is less likely to remain in the inclined section.

(3) The overlapping portion may be disposed not to overlap the second inclined section or to cover a part of the second inclined section. If the overlapping portion is configured to cover not only the entire area of the inclined section but also the entire area of the second inclined section. the overlapping portion is more likely to be parallel to the inclined section and the second inclined section. In such a configuration, moisture is more likely to remain in the overlapping portion and therearound. Because the overlapping portion does not overlap the second inclined section or covers the part of the second inclined section, the overlapping portion is less likely to be parallel to the inclined section and the second inclined section. Therefore, the moisture is less likely to remain in the overlapping portion and therearound.

(4) The display board may include a terminal that is formed from a lower layer-side metal film disposed in a layer lower than the insulating film in the non-display area. The insulating film may be configured such that the insulating film voided area overlaps a terminal central section of the terminal. The at least one inclined section may be disposed to overlap a terminal peripheral section of the terminal for an entire periphery of the terminal peripheral section. The overlapping portion may overlap the insulating film voided area and the at least one inclined section for entire peripheries of the insulating film voided area and the at least one inclined section. In the insulating film having the configuration in which the insulating film voided area overlaps the terminal central section of the terminal, the inclined section is disposed to overlap the terminal peripheral section of the terminal for the entire periphery. Because the overlapping portion overlaps the insulating film voided area and the inclined section for the entire peripheries, moisture is less likely to remain in the inclined section and therearound for the entire periphery.

(5) The overlapping portion may overlap the insulating film voided area and the at least one inclined section for entire peripheries of the insulating film voided area and the at least one inclined section. According to the configuration, electrical performance of the terminal can be maintained with the overlapping portion formed from the upper layer-side metal film.

(6) The display board may include terminals, terminal lines, and a second insulating film. The terminals may be formed from a lower layer-side metal film disposed in a layer lower than the insulating film in the non-display area. The terminal lines may be formed from, the lower layer-side metal film and connected to the terminals in the non-display area. The second insulating film may be disposed in a layer upper than the insulating film. The insulating film may be configured such that the insulating film voided area overlaps the terminals to cross the terminals. The at least one inclined section may be disposed to cross the terminal lines. The overlapping portion may be formed from a section of the second insulating film and disposed to cross the terminal lines. In the insulating film having such a configuration in which the insulating film voided area overlaps the terminals to cross the terminals, the inclined section is disposed to cross the terminal lines. The overlapping portion is formed from the section of the second insulating film disposed in the layer upper than the insulating film and disposed to cross the terminal lines. Therefore, the retention of moisture in the inclined section and therearound can be reduced without developing a short circuit between the adjacent terminal lines.

(7) The display board may include a display driver that is mounted in the non-display area and connected to the terminal. The terminal connected to the display driver may be exposed to the outside in a stage prior to the mounting of the display driver. However, moisture is less likely to remain in the inclined section of the insulating film disposed closer to the terminal and therearound because of the overlapping portion.

(8) The insulating film may include an insulating film central portion and an insulating film peripheral portion that are separated from each other by the insulating film voided area that is formed in a frame shape to surround the display area. The at least one inclined section may include an inclined section at the insulating film central portion extending for an entire periphery of the insulating film central portion and an inclined section at the insulating film peripheral portion extending for an entire periphery of the insulating film peripheral portion. The overlapping portion may overlap the insulating film voided area and the at least one inclined section. Even if moisture from the outside enters the insulating film peripheral portion, the moisture in the insulating film peripheral portion is less likely to enter the insulating film central portion because the insulating film central portion is separated from the insulating film peripheral portion by the insulating film voided area that is formed in the frame shape to surround the display area. Because the moisture is less likely to remain in the inclined sections at the insulating film central portion and the insulating film peripheral portion for the entire peripheries because of the overlapping portion, the entrance; of the moisture into the insulating film central portion can be further properly reduced.

To solve the problem described earlier, a display device according to the present invention includes the display board described above and a common board opposed to the display board. In the display device having such a configuration, the display failure resulting from retention of moisture in the display board is reduced. Therefore, the display device has high display reliability.

### Advantageous Effect of the Invention

According to the present invention, a display failure resulting from retention of moisture can be reduced.

### BRIEF DESCRIPTION OF THE DRAWINGS

FIG. 1 is a plan view of a liquid crystal panel included in a liquid crystal display device according to a first embodiment of the present invention.

FIG. 2 is a plan view illustrating two-dimensional arrangement of a common electrode on an array board included in the liquid crystal panel.

FIG. 3 is a schematic cross-sectional view illustrating a cross-sectional configuration of the liquid crystal panel in a display area.

FIG. 4 is a plan view schematically illustrating a wiring configuration in a display area of an array board included in the liquid crystal panel.

FIG. 5 is a plan view schematically illustrating a wiring configuration in a display area of a CF board included in the liquid crystal panel.

FIG. 6 is a cross-sectional view along line vi-vi in FIG. 4.

FIG. 7 is a cross-sectional view along line vii-vii in FIG. 4.

FIG. 8 is a plan view schematically illustrating a wiring configuration in a non-display area of the array board included in the liquid crystal panel.

FIG. 9 is a cross-sectional view along line ix-ix in FIG. 8.

FIG. 10 is a cross-sectional view along line x-x in FIG. 8.

FIG. 11 is a magnified cross-sectional view of an overlapping section and therearound in FIG. 9.

FIG. 12 is a magnified plan view schematically illustrating a wiring configuration in a non-display area of an array board includes in a liquid crystal panel according to a second embodiment of the present invention.

FIG. 13 is a cross-sectional view along line xiii-xiii in FIG. 12.

FIG. 14 is a cross-sectional view along line xiv-xiv in FIG. 12.

FIG. 15 is a plan view of an array board according to a third embodiment of the present invention.

FIG. 16 is a cross-sectional view along line xvi-xvi in FIG. 15.

FIG. 17 is a cross-sectional view of an input terminal and therearound in a non-display area of an array board included in a liquid crystal panel according to a fourth embodiment of the present invention along the Y-axis.

FIG. 18 is a cross-sectional view of the input terminal and therearound in the non-display area of the array board included in the liquid crystal panel along the X-axis direction.

FIG. 19 is a cross-sectional view of an input terminal and therearound in a non-display area of an array board included in a liquid crystal panel according to other embodiment (1) of the present invention.

FIG. 20 is a cross-sectional view of the input terminal and therearound in the non-display area of the array board included in the liquid crystal panel along the X-axis direction.

FIG. 21 is a cross-sectional view of an input terminal and therearound in a non-display area of an array board included in a liquid crystal panel according to other embodiment (2) of the present invention.

FIG. 22 is a cross-sectional view of a section between input terminals and therearound in the non-display area of the array board included in the liquid crystal panel along the Y-axis direction.

FIG. 23 is a cross-sectional view of insulating film voided areas and therearound in a non-display area of the array board included in the liquid crystal panel according to other embodiment (3) of the present invention.

### MODE FOR CARRYING OUT THE INVENTION

### First Embodiment

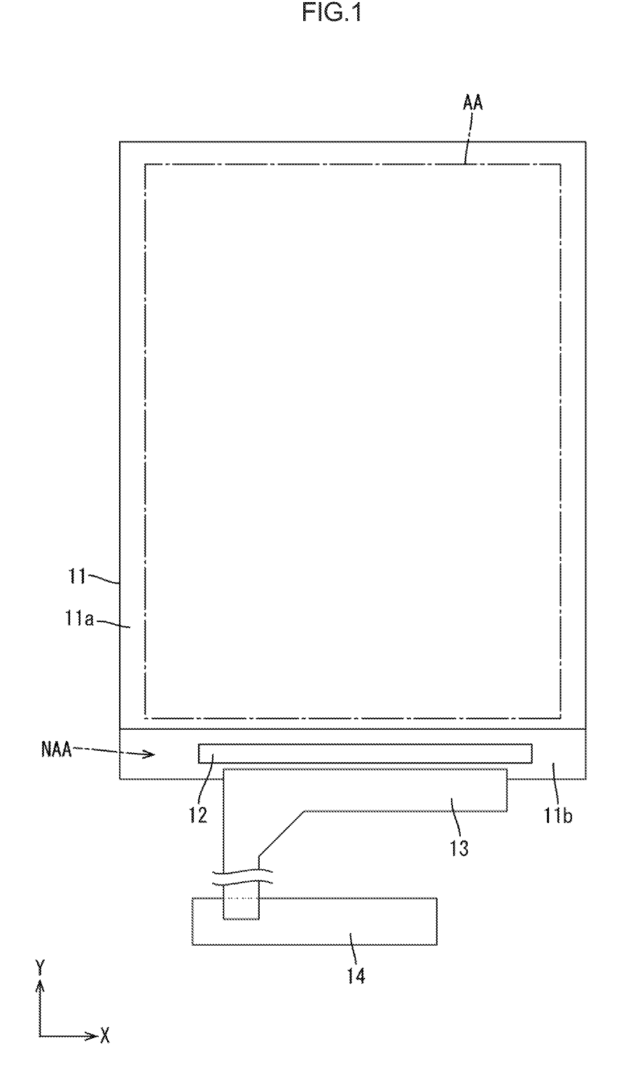

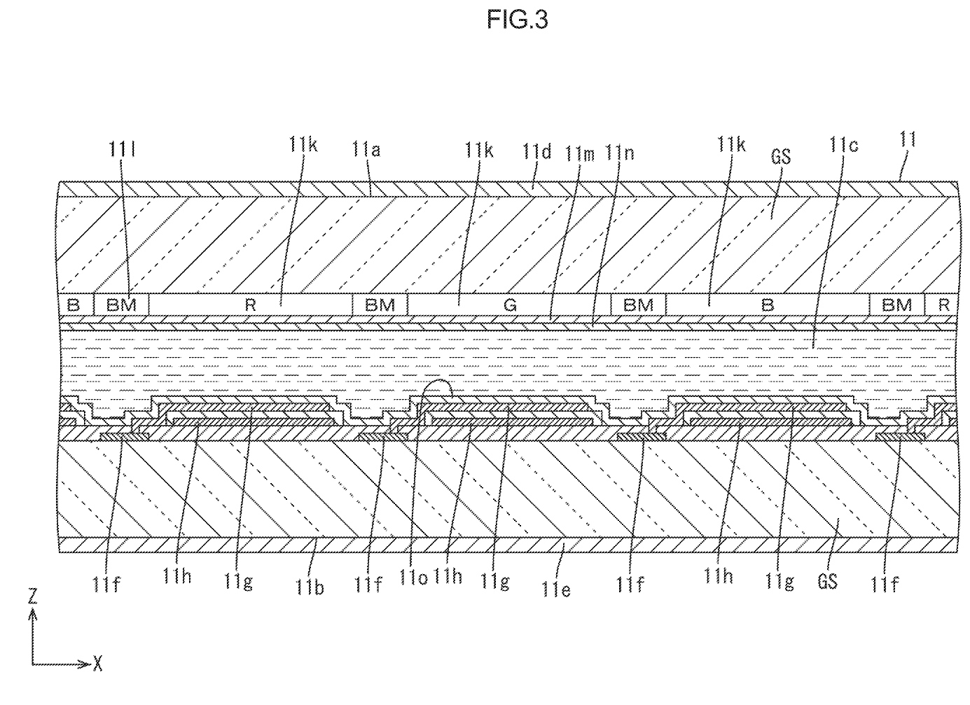

A first embodiment of the present invention will be described with reference to FIGS. 1 to 11. In this section, a liquid crystal panel 11 (a display device, a display panel) included in a liquid crystal display device 10 with a position input function will be described. X-axes, Y-axes, and Z-axes may be present in drawings. The axes in each drawing correspond to the respective axes in other drawings to indicate the respective directions. Upper sides and lower sides in in FIGS. 3, 6 and 7 correspond to a front side and a rear side of the liquid crystal panel 11, respectively.

The liquid crystal display device 10 has a rectangular overall shape. As illustrated in FIG. 1, the liquid crystal display device 10 includes at least the liquid crystal panel 11 and a backlight unit (a lighting device). The liquid crystal panel 11 is configured to display images. The backlight unit is an external light source disposed behind the liquid crystal panel 11 and configured to apply light to the liquid crystal panel 11 for displaying images. Among components of the liquid crystal display device 10, the liquid crystal panel 11 will be described in detail but other components including the backlight unit will not be described in detail because they are well known.

As illustrated in FIG. 1, the liquid crystal panel 11 has a vertically-long rectangular overall shape. At a position closer to a first end of the liquid crystal panel 11 with respect to a long direction of the liquid crystal panel 11 (the upper side in FIG. 1), a display area AA (an active area) in which images are displayed is provided. A driver 12 (a display driver) and a flexible circuit board 13 for supplying various signals are mounted at positions closer to a second end of the liquid crystal panel 11 with respect to the long direction of the liquid crystal panel 11 (the lower side in FIG. 1). In the liquid crystal panel 11, the area outside the display area AA is the non-display area NAA (a non-active area) in which images are not displayed. The non-display area NAA includes a frame-shaped area that surrounds the display area AA (a frame-shaped section of a CF board 11a, which will be described later) and an area that is provided at the second end with respect to the long direction (a section of an array board 11b which is exposed without overlapping the CF board 11a, which will be described later). The area provided at the second end with respect to the long direction includes a mounting area (an attachment area) in which the driver 12 and the flexible circuit board 13 are mounted. The short direction of the liquid crystal panel 11 corresponds with the X-axis direction and the long direction of the liquid crystal panel 11 corresponds with the Y-axis direction. Furthermore, the normal direction to the plate surface (the display surface) corresponds with the Z-axis direction. A control circuit board 14 (a control circuit board) which is a signal source is connected to an end of the flexible circuit board 13 on an opposite side from the liquid crystal panel 11 side. In FIG. 1, a chain line in a frame shape indicates an outline of the display area AA and an area outside the chain line is the non-display area NAA.

Components mounted or connected to the liquid crystal panel 11 (the driver 12, the flexible circuit board 13, and the control circuit board 14) will be described. As illustrated in FIG. 1, the driver 12 (the display driver) is an LSI chip including drive circuits. The driver 12 is configured to operate according to signals supplied by the control circuit board 14 to process the input signal supplied by the control circuit board 14, to generate output signals, and to output the output signals to the display area AA in the liquid crystal panel 11. The driver 12 has a vertically-long rectangular shape (an elongated shape that extends along the short side of the liquid crystal panel 11) in a plan view. The driver 12 is directly mounted in the non-display area NAA of the liquid crystal panel 11 (or the array board 11b, which will be described later), that is, mounted by the chip-on-glass (COG) mounting method. A long-side direction and a short-side direction of the driver 12 correspond to the X-axis direction (the short-side direction of the liquid crystal panel 11) and the Y-axis direction (the long-side direction of the liquid crystal panel 11), respectively.

As illustrated in FIG. 1, the flexible circuit board 13 includes a base member made of synthetic resin having insulating property and flexibility (e.g., polyimide resin). A number of traces are formed on the base member (not illustrated). As illustrated in FIG. 1, a first end of the long dimension of the flexible circuit board 13 is connected to the control circuit board 14 as described above. A second end of the long dimension of the flexible circuit board 13 is connected to the liquid crystal panel 11 (the array board 11b, which will be described later). At the ends of the long dimension of the flexible circuit board 13, sections of the traces are exposed to the outside and configured as terminals (not illustrated). The terminals are electrically connected to the control circuit board 14 and the liquid crystal panel 11. With this configuration, signals supplied by the control circuit board 14 are transmitted to the liquid crystal panel 11. The control circuit board 14 is disposed on the back side of the backlight unit. The control circuit board 14 includes a substrate made of paper phenol or glass epoxy resin and electronic components mounted on the substrate and configured to supply various signals to the driver 12. Traces (conductive paths) which are not illustrated are formed in predetermined patterns. The first end of the flexible circuit board 13 is electrically and mechanically connected to the control circuit board 14 via an anisotropic conductive film (ACF), which is not illustrated.

The liquid crystal panel 11 will be described. As illustrated in FIG. 3, the liquid crystal panel 11 includes a pair of boards 11a and 11b and a liquid crystal layer 11c (a medium layer) in a space between the boards 11a and 11b. The liquid crystal layer 11c includes liquid crystal molecules having optical characteristics that vary according to application of electric field. The liquid crystal layer 11c is surrounded and sealed by a sealing agent disposed between the boards 11a and 11b. The sealing agent is not illustrated. One of the boards 11a and 11b on the front is the CF board 11a (a common board) and one on the rear (on the back) is the array board 11b (a display board, an active matrix board, a component board). The CF board 11a and the array board 11b include glass substrates GS and various films that are formed in layers on inner surfaces of the glass substrates GS. Polarizing plates 11d and 11e are attached to outer surfaces of the boards 11a and 11b, respectively.

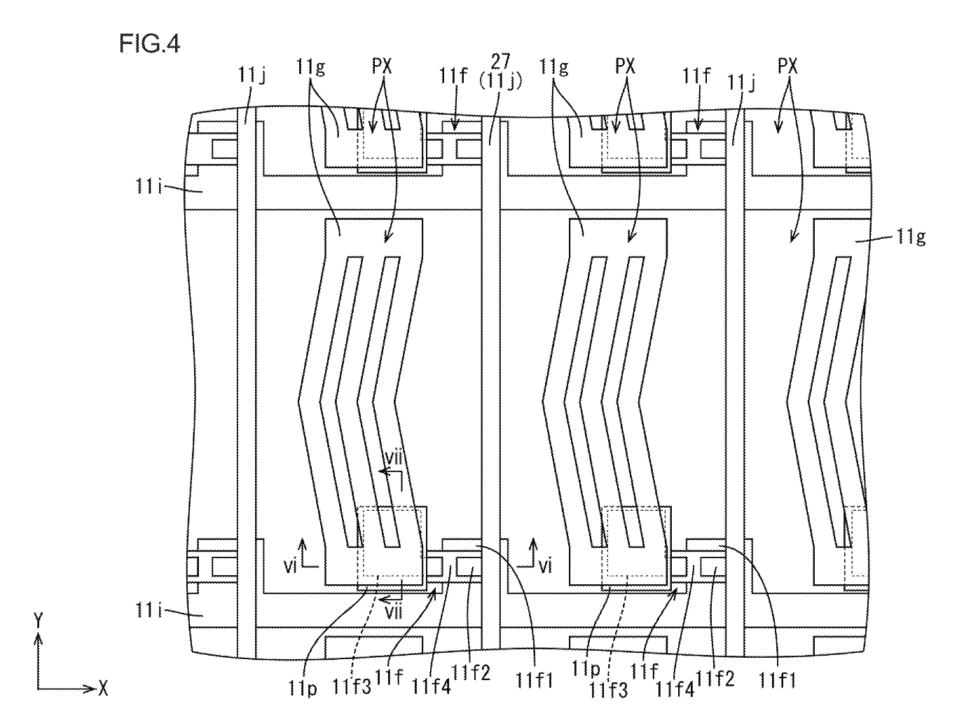

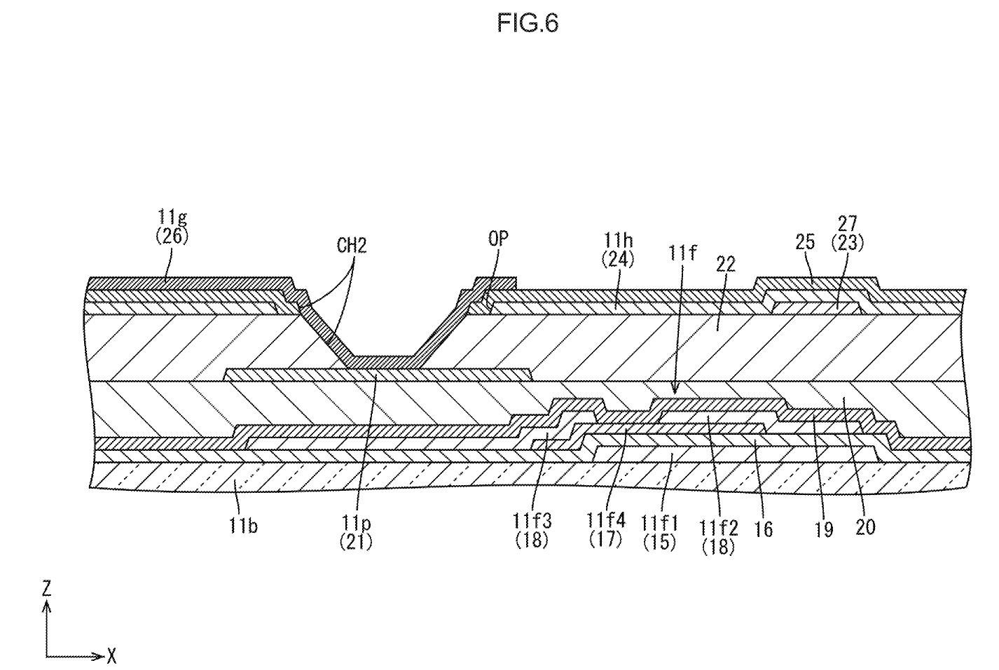

On an inner surface of the array board 11b (on the liquid crystal layer 11c side in the display area AA, an opposed surface opposed to the CF board 11a), as illustrated in FIGS. 4 and 6, thin film transistors 11f (TFTs, display components) which are switching components and pixel electrodes 11g are arranged in a matrix. Gate lines 11i (scan lines) and source lines 11j (data lines, signal lines, component lines) are routed in a grid to surround the TFTs 11f and the pixel electrodes 11g. The gate lines 11i and the source lines 11j are connected to gate electrodes 11f1 and source electrodes 11f2 of the TFTs 11f, respectively. The pixel electrodes 11g are connected to drain electrodes 11f3 of the TFTs 11f. The TFTs 11f are driven based on signals supplied to the gate lines 11i and the source lines 11j. Voltages are applied to the pixel electrodes 11g in accordance with the driving of the TFTs 11f. The TFTs 11f include channels 11f4 that connect the drain electrodes 11f3 to the source electrodes 11f2. In this embodiment, a direction in which the gate lines 11i extend and a direction in which the source lines 11j extend correspond with the X-axis direction and the Y-axis direction in each drawing, respectively. The pixel electrodes 11g are disposed in quadrilateral areas defined by the gate lines 11i and the source lines 11j. Each pixel electrode 11g includes slits. The pixel electrodes 11g area connected to the drain electrodes 11f3 of the respective TFTs 11f via the TFT connecting portions 11p (component connecting portions). A common electrode 11h is disposed on the inner surface of the array board 11b in addition to the pixel electrodes 11g. When a potential difference is created between the electrodes 11g and 11h, a fringe electric field (an oblique electric field) including a component along the plate surface of the array board 11b and a component in the normal direction to the plate surface of the array board 11b. The liquid crystal panel 11 operates in fringe field switching (FFS) mode that is an improved version of in-plane switching (IPS) mode.

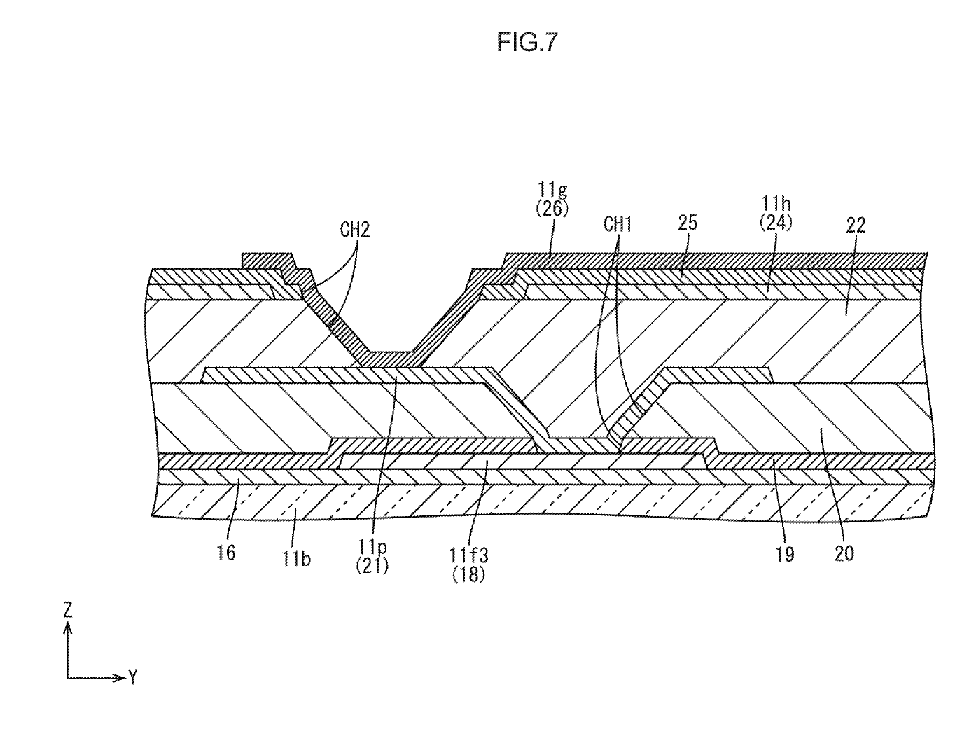

Various films are formed in layers on an inner surface of the array board 11b by the known photolithography method. The films will be described. As illustrated in FIGS. 6 and 7, on the array board 11b, a first metal film 15 (a gate metal film, a lower layer-side metal film), a gate insulating film 16 (a lower layer-side insulating film, an insulating film), a semiconductor film 17, a second metal film 18 (a source metal film, an upper layer-side metal film), a first interlayer insulating film 19 (an upper layer-side insulating film, an insulating film), a first planarization film 20 (a second insulating film), a third metal film 21, a second planarization film 22, a fourth metal film 23, a first transparent electrode film 24 (a lower layer-side transparent electrode film), a second interlayer insulating film 25, and a second transparent electrode film 26 (an upper layer-side transparent electrode film) are layered in this sequence from a lower layer side (a glass substrate GS). An alignment film 11o disposed in a layer upper than the second transparent electrode film 26 is not illustrated in in FIGS. 6 and 7.

The first metal film 15 is a laminated film that includes three layers: a titanium (Ti) layer; an aluminum (Al) layer; and a titanium layer. The gate lines 11i are formed from the first metal film 15. As illustrated in FIGS. 6 and 7, the gate insulating film 16 is disposed in a layer at least upper than the first metal film 15. The gate insulating film 16 may be made of inorganic material such as silicon oxide (SiO2). The gate insulating film 16 is disposed between the first metal film 15 (the gate lines 11i) and the second metal film 18 (the source lines 11j) that are insulated from each other by the gate insulating film 16. The semiconductor film 17 is disposed in a layer upper than the gate insulating film 16. The semiconductor film 17 is a thin film made of substantially transparent oxide semiconductor. An oxide semiconductor of the semiconductor film 17 may be an In—Ga—Zn—O based semiconductor (indium gallium zinc oxide) containing indium (In), gallium (Ga), zinc (Zn), and oxygen (O). The In—Ga—Zn—O based semiconductor is a ternary oxide containing indium (In), gallium (Ga), and zinc (Zn). The ratio (the compound ratio) of indium to gallium and zinc is not limited to a specific ratio. Examples of the ratio include: In:Ga:Zn=2:2:1, In:Ga:Zn=1:1:1, In:Ga:Zn=1:1:2. In this embodiment, the ratio of Indium to gallium and zinc in the In—Ga—Zn—O based semiconductor is 1:1:1. The oxide semiconductor (the In—Ga—Zn—O based semiconductor) may have amorphous properties but preferably have crystalline properties, that is, including crystalline substances. A preferable oxide semiconductor having crystalline properties may be a crystalline In—Ga—Zn—O based semiconductor with the c-axis is substantially perpendicular to a layer surface. An example of crystalline structures of such an oxide semiconductor (the In—Ga—Zn—O based semiconductor) is disclosed in Japanese Unexamined Patent Application Publication No. 2012-134475. Whole disclosure of Japanese Unexamined Patent Application Publication No. 2012-134475 is incorporated by reference.

As illustrated in FIGS. 6 and 7, the second metal film 18 is disposed in a layer upper than at least the semiconductor film 17. The second metal film 18 is a laminated film that includes three layers: a titanium layer; an aluminum layer; and a titanium layer, similar to the first metal film 15. The source lines 11j, the source electrodes 11f2, and the drain electrodes 11f3 are formed from the second metal film 18. The first interlayer insulating film 19 is disposed in a layer upper than at least the second metal film 18. The first interlayer insulating film 19 is made of inorganic material such as silicon oxide (SiO₂). The first planarization film 20 is disposed in a layer upper than the first interlayer insulating film 19. The first planarization film 20 is made of acrylic resin material that is an organic material (e.g., polymethylmethacrylate resin (PMMA)). The first interlayer insulating film 19 and the first planarization film 20 are disposed in a layer between the third metal film 21 and the second metal film 18 and the semiconductor film 17 that are insulated from each other by the first interlayer insulating film 19 and the first planarization film 20. The third metal film 21 is disposed in a layer upper than at least the first planarization film 20. The third metal film 21 is a laminated film that includes three layers: a titanium layer; an aluminum, layer; and a titanium layer, similar to the first metal film 15 and the second metal film 18. The TFT connecting portions 11p in the display area AA and input terminals 28 and terminal lines 29 in the non-display area NAA, which will be described later, are formed from the third metal film 21.

As illustrated in FIGS. 6 and 7, the second planarization film 22 is disposed in a layer upper than the third metal film 21 and the first planarization film 20. The second planarization film 22 is made of acrylic resin material that is an organic material (e.g., polymethylmethacrylate resin (PMMA)) similar to the first planarization film 20. The second planarization film 22 is disposed in the layer between the third metal film 21 and the fourth metal film 23 and the first transparent electrode film 24 that are insulated from each other by the second planarization film 22. The fourth metal film 23 is disposed in a layer upper than at least the second planarization film 22. The third metal film 21 is a laminated film that includes three layers: a titanium layer; an aluminum layer; and a titanium layer, similar to the first metal film 15, the second metal film 18, and the third metal film 21. The position detection lines 11q, which will be described later, are formed from the fourth metal film 23. The first transparent electrode film 24 is disposed in a layer upper than the fourth metal film 23 and the first planarization film 20. The first transparent electrode film 24 is made of transparent electrode material such as indium tin oxide (ITO) and zinc oxide (ZnO). The first transparent electrode film 24 forms the common electrode 11h. The second interlayer insulating film 25 is disposed in a layer upper than at least first transparent electrode film 24. The second interlayer insulating film 25 is made of inorganic material such as silicon nitride (SiNx). The second interlayer insulating film 25 is disposed in the layer between the first transparent electrode film 24 and the second transparent electrode film 26 that are insulated from each other by the second interlayer insulating film 25. The second transparent electrode film 26 is disposed in a layer upper than the second interlayer insulating film 25. The second transparent electrode film 26 is made of transparent electrode material such as indium tin oxide (ITO) and zinc oxide (ZnO) similar to the first transparent electrode film 24. The pixel electrodes 11g are formed from the second transparent electrode film 26. Among the insulating films 16, 19, 20, 22, and 25 described above, the first planarization film 20 and the second planarization film 22 are the organic insulating films having thicknesses larger than those of the other insulating films (inorganic insulating films) 16, 19, and 25. The first planarization film 20 and the second planarization film 22 have functions of planarizing surfaces. Among the insulating films 16, 19, 20, 22, and 25 described above, the gate insulating film 16, the first interlayer insulating film 19, and the second interlayer insulating film 25 other than the first planarization film 20 and the second planarization film 22 are the inorganic insulating films having thicknesses smaller than those of the organic insulating films, that is, the first planarization film 20 and the second planarization film 22.

As illustrated in FIG. 4, each TFT connecting portion 11p (the component connecting portion) has a vertically-long rectangular shape. The TFT connecting portions 11p are two-dimensionally arranged to overlap the drain electrodes 11f3 of the corresponding TFTs 11f and the corresponding pixel electrodes 11g in a plan view. As illustrated in FIG. 7, the first interlayer insulating film 19 and the first planarization film 20 include first TFT contact holes CH1 (first component contact holes) in areas that overlap the first TFT connecting portions 11p and the drain electrodes 11f3. The TFT connecting portions 11p in the upper layer are connected to the drain electrodes 11f3 in the lower layer through the first TFT contact holes CH1. As illustrated in FIG. 6, the second planarization film 22 and the second interlayer insulating film 25 include second TFT contact holes CH2 (second component contact holes, component contact holes) in areas that overlap the TFT connecting portions lip and the drain electrodes 11f3 but not overlap the first TFT contact holes CH1. The pixel electrodes 11g in the upper layer are connected to the TFT connecting portions 11p in the lower layer through the second TFT contact holes CH2. Although four insulating films 19, 20, 22, and 25 are disposed between the pixel electrodes 11g and the drain electrodes 11f3, the pixel electrodes 11g and the drain electrodes 11f3 are connected to each other via the TFT connecting portions 11p disposed therebetween. Sections of the common electrode 11h overlapping the second TFT contact holes CH2 (sections of the TFT connecting portions lip) include holes OP to reduce an occurrence of short circuit between the common electrode 11h and the pixel electrodes 11g. The insulating films 16, 19, 20, 22, and 25 are formed in solid patterns to cover about the entire display area AA of the array board 11b except for the contact holes CH1 and CH2.

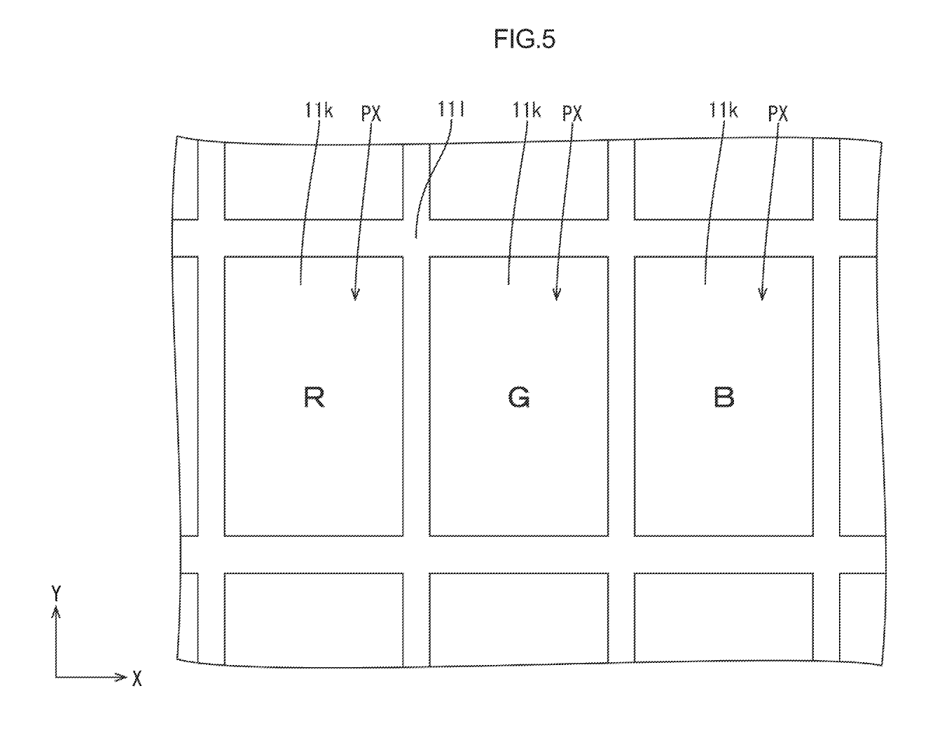

As illustrated in FIGS. 3 and 5, on the inner surface of the CF board 11a in the display area AA, color filters 11k are arranged at positions opposed to the pixel electrodes 11g on the array board 11b. The color filters 11k include red (R), green (G), and blue (B) color portions in three colors. The R color portions, the G color portions, and the B color portion are repeatedly arranged to form a matrix. The color portions (the pixels PX) of the color filters 11k arranged in the matrix are separated from one another with a light blocking portion 111 (a black matrix). With the light blocking portion 111, color mixture of different colors of light rays that pass through the color portions is less likely to occur. The light blocking portion 111 is formed in a grid in the plan view. The light blocking portion 111 includes dividing sections and a frame section. The dividing sections form a grid shape in the plan view and separate the color portions from one another. The frame section has a frame shape (a picture frame shape) in the plan view and surrounds the dividing sections from, the peripheral sides. The dividing sections of the light blocking portion 111 are disposed to overlap the gate lines 11i and the source lines 11j in the plan view. The frame section of the light blocking portion 111 extends along the sealing member and has a vertically-long rectangular shape in the plan view. An overcoat film 11m (a planarization film) is disposed over surfaces of the color filters 11k and the light blocking portion 111 on the inner side. In the liquid crystal panel 11, each color portion of the color filter 11k and the pixel electrode 11g that is opposed to the color portion form a single pixel PX. The pixels PX include red pixels, green pixels, and blue pixels. The red pixels include the R color portions of the color filters 11k. The green pixels include the G color portions of the color filters 11k. The blue pixels include the B color portions of the color filters 11k. The pixels PX in three colors are repeatedly arranged along the row direction (the X-axis direction) on the plate surface of the liquid crystal panel 11 to form pixel lines. A number of the pixel lines are arranged along the column direction (the Y-axis direction). Namely, a number of the pixels PX are arranged in a matrix in the display area AA of the liquid crystal panel 11. Alignment films 11n and 11o are formed in inner most layers on the boards 11a and 11b to contact the liquid crystal layer 11c. The alignment films 11n and 11o are for orientating the liquid crystal molecules in the liquid crystal layer 11c.

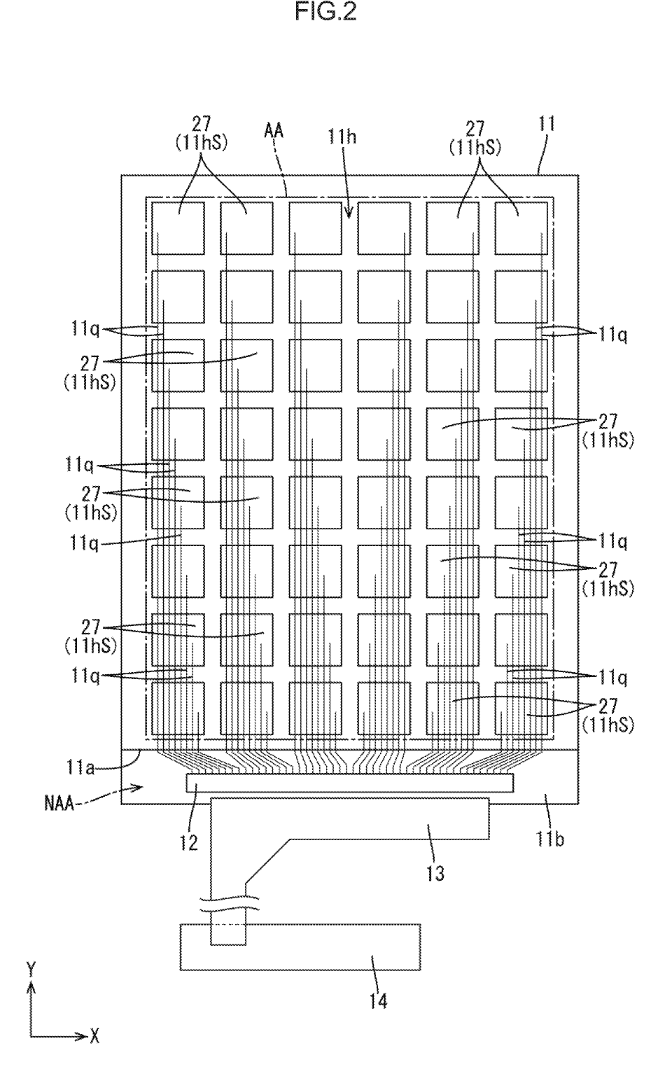

As described earlier, the liquid crystal panel 11 according to this embodiment has the display function and the position input function (the position detection function). The display function is for displaying images. The position input function is for detecting positions (input positions) input by the user based on images that are displayed. The liquid crystal panel 11 includes a touchscreen pattern integrated therein (in-cell touchscreen technology) for performing the position input function. The touchscreen pattern uses a so-called projection type electrostatic capacitance method. A detection method of the touchscreen pattern is a self-capacitance method. As illustrated in FIG. 2, the touchscreen pattern is formed on the array board 11b of the pair of boards 11a and 11b. The touchscreen pattern includes position detection electrodes 27 arranged in a matrix within a plane of the array board 11b. The position detection electrodes 27 are disposed in the display area AA of the array board 11b. The display area AA of the liquid crystal panel 11 substantially corresponds with a touching area in which input positions can be detected. The non-display area NAA of the liquid crystal panel 11 substantially corresponds with a non-touching area in which the input positions cannot be detected. When the user brings his or her finger (a position detection object), which is a conductive member, closer to the surface of the liquid crystal panel 11 to input a position based on the image displayed in the display area AA of the liquid crystal panel 11, an electrostatic capacitance is obtained between the finger and the position detection electrode 27. The electrostatic capacitance detected by the position detection electrode 27 closer to the finger varies from the electrostatic capacitance when the finger is away from the position detection electrode 27 as the finger approaches thereto. The electrostatic capacitance detected at the position detection electrode 27 closer to the finger is different from the electrostatic capacitance detected at any of the other position detection electrodes 27 away from the finger. Therefore, the input position can be detected based on the difference in electrostatic capacitance. A parasitic capacitance may exist between the position detection electrode 27 away from the finger and a conductive member other than the finger.

The position detection electrodes 27 are included in the common electrode 11h in the array board 11b. As illustrated in FIG. 2, the common electrode 11h includes common electrode segments 11hS that are separated from each other and arranged in a grid within the plane of the array board 11b. The common electrode segments 11hS are configure as the position detection electrodes 27. In comparison to a configuration in which position detection electrodes are provided separately from the common electrode 11h, the configuration of this embodiment is more preferable for simplifying the structure and reducing the cost. The position detection electrodes 27 (or the common electrode segments 11hS) are arranged in lines along the X-axis direction (the row direction) and in lines along the Y-axis direction (the column direction) to form a matrix. Each position detection electrode 27 has a rectangular shape in a plan view and sides, each of which is some millimeters. Namely, each position detection electrode 27 is larger than each pixel PX (the pixel electrode 11g) in the plan view and disposed in an area in which the multiple pixels PX are arranged along the X-axis direction and Y-axis direction. FIG. 2 schematically illustrates the arrangement of the position detection electrodes 27. The number and the arrangement of the position detection electrodes 27 may be altered from those in the drawing where appropriate.

As illustrated in FIG. 2, position detection lines 11q are connected to the position detection electrodes 27 (or the common electrode segments 11hS). In the display area AA, the position detection lines 11q linearly extend along the Y-axis direction, that is, the extending direction of the source lines 11j (the column line). The position detection lines 11q have lengths corresponding to the position detection electrodes 27 to which the position detection lines 11q are connected, respectively. Namely, a first end of each position detection line 11q is disposed over the corresponding position detection electrode 27 to which the first end is connected in the display area AA and a second end of each position detection line 11q disposed in the non-display area NAA is connected to the driver 12. The driver 12 is configured to drive the TFTs 11f for image display and the position detection electrodes 27 for position detection. Namely, the driver 12 has a display function and a position detection function. As described earlier, the position detection lines 11q are formed from the fourth metal film 23 and the position detection electrodes 27, that is, the common electrode 11h is formed from the first transparent electrode film 24. The position detection electrodes 11q are directly connected to the position detection electrodes 27 without contact holes. The position detection lines 11q are connected to not only the position detection electrodes 27 to which the respective position detection electrodes 27 are connected but also other position detection electrodes 27 between the position detection electrodes 27 and the driver 12. According to the configuration in which the position detection lines 11q are connected to the position detection electrodes 27 in each column (the position detection electrodes 27 arranged along the extending direction of the position detection lines 11q), the position detection electrode 27 to which the position is actually input can be identified by extracting a combination of the position detection lines 11q that have detected the position from the position detection lines 11q in the same column. As illustrated in FIG. 4, the position detection lines 11q are disposed to overlap the specific source lines 11j (the light blocking portion 111) in the plan view but not the pixels PX. According to the arrangement, a reduction in aperture ratio of the pixels PX by the position detection lines 11q is less likely to occur.

Next, the configuration of the section of the array board 11b in the non-display area NAA will be described. A non-overlapping section of the array board in the non-display area NAA does not overlap the CF board 11a. As illustrated in FIG. 1, the end of the flexible circuit board 13 and the driver 12 are mounted in the non-overlapping area. The end of the flexible circuit board 13 is disposed in an edge area of the non-overlapping section along the short direction of the array board 11b (the X-axis direction). The driver 12 is disposed on the array board 11b closer to the display area AA relative to the flexible circuit board 13. In the driver 12 mounting area of the array board 11b in which the driver 12 is mounted, output terminals (not illustrated) and the input terminals 28 (terminals) are disposed. The output terminals are for outputting signals to the driver 12. The input terminals 28 are for receiving signals from the driver 12. In the flexible circuit board 13 mounting area of the array board 11b in which the flexible circuit board 13 is mounted, flexible board connecting terminals (not illustrated) connected to the flexible circuit board 13 are disposed. The input terminals 28 are disposed closer to the display area AA in comparison to the other terminals (the output terminals and the flexible circuit board connected terminals) with respect to the Y-axis direction.

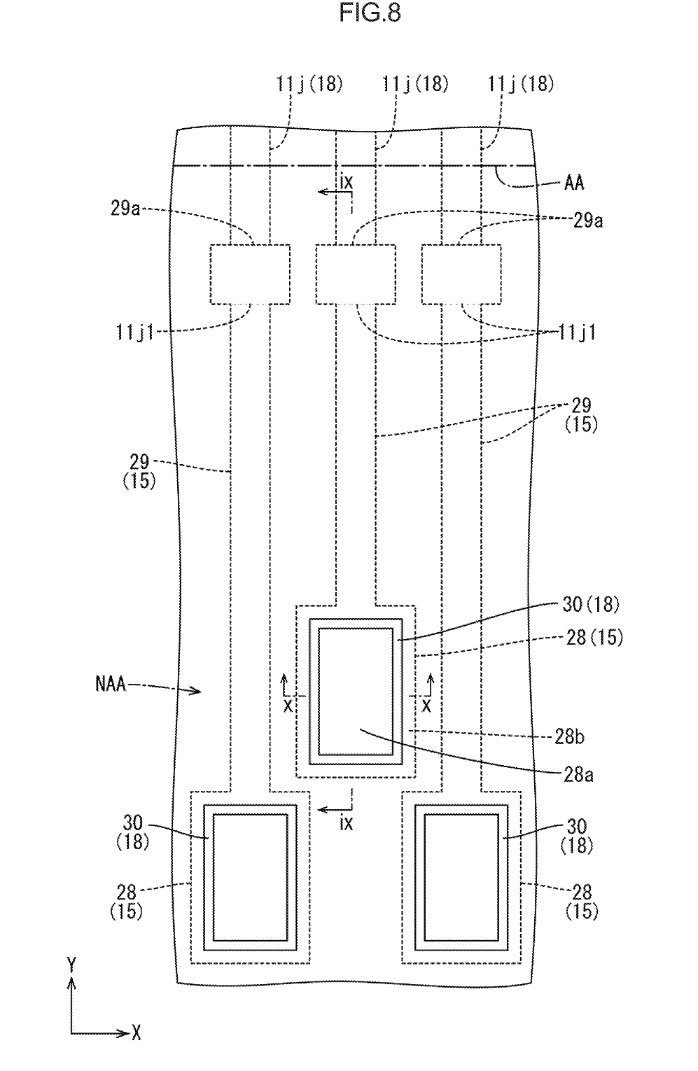

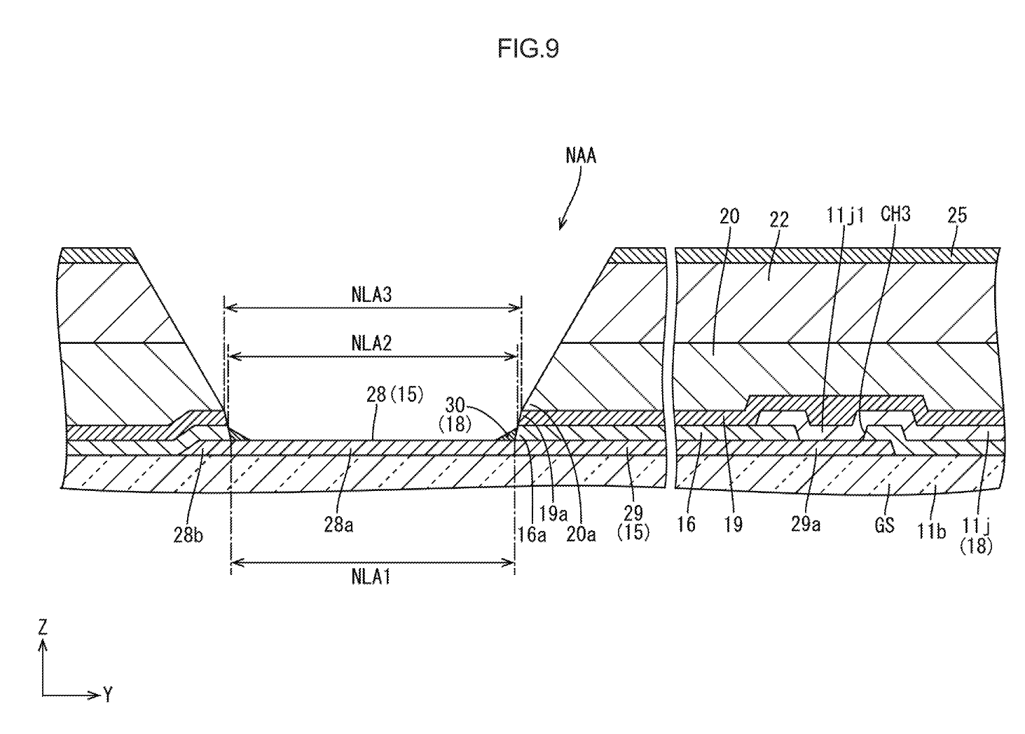

As illustrated in FIG. 8, the input terminals 28 are two-dimensionally arranged in a zigzag pattern in the driver 12 mounting area and connected to the terminal lines 29, which will be described next. The terminal lines 29 are disposed at predefined intervals along the X-axis direction in the section of the array board 11b in the non-display area NAA. The terminal lines 29 extend in the Y-axis direction. First ends of the terminal lines 29 are connected to the input terminals 28 and second ends of the terminal lines 29 (on the display area AA side) are connected to the ends of the source lines 11j, respectively. Large sections of the source lines 11j are disposed in the display area AA but some sections of the source lines 11j (including line overlapping sections 11j1) are disposed, in the non-display area NAA. As illustrated in FIG. 9, the input terminals 28 and the terminal lines 29 are formed from the first metal film 15 that also forms the gate lines 11i and the gate electrodes 11f1. The terminal lines 29 are disposed in a layer lower than the source lines 11j to which the terminal lines 29 are connected via the gate insulating film 16. The ends of the terminal lines 29 on an opposite side from the input terminals 28 and ends of the source lines 11j on an opposite side from the TFTs 11f are disposed to overlap each other in the plan view in the section of the array board 11b in the non-display area NAA. Overlapping sections of the source lines 11j and the terminal lines 29 are defined as line overlapping sections 11j1 and 29a. The gate insulating film 16 disposed between the terminal lines 29 and the source lines 11j include line contact holes CH3 at positions overlapping the line overlapping sections 11j1 of the terminal lines 29 and the line overlapping sections 29a of the source lines 11j in the plan view. The line contact holes CH3 are for connecting the line overlapping sections 11j1 and 29a to each other. The signals output by the driver 12 are fed to the source electrodes 11f2 of the TFTs 11f via the input terminals 28, the terminal lines 29, and the source lines 111.

As illustrated in FIG. 8, sections of the insulating films 16, 19, 20, 22, and 25 closer to the driver 12 mounting area and the flexible circuit board 13 mounting area in the non-display area of the array board 11b mostly remain in the solid patterns except for island-shaped areas overlapping the terminals (including the input terminals 28, the output terminals, and the flexible board connecting terminals) are removed to form holes. Areas including the holes are defined as insulating film voided areas (including insulating film voided areas NLA1 to NLA3, which will be described later). The insulating film voided areas NLA1 to NLA3 are positioned to overlap an input terminal central section 28a (a terminal central section) of the corresponding input terminal 28. In this section, only the gate insulating film voided area NLA1 of the gate insulating film 16, the first interlayer insulating film voided area NLA2 of the first interlayer insulating film 19, and the first planarization film voided area NLA3 of the first planarization film 20 will be described with reference symbols. The input terminal central section 28a and the insulating film voided areas NLA1 to NLA3 have vertically-long rectangular shapes in a plan view with outlines similar to an outline of the input terminal 28.

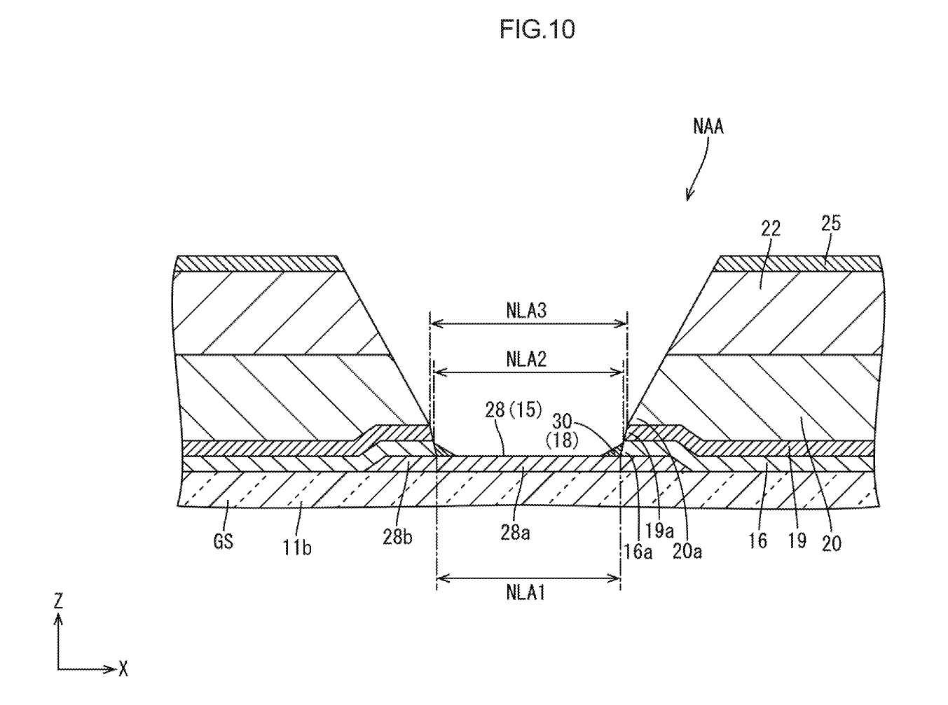

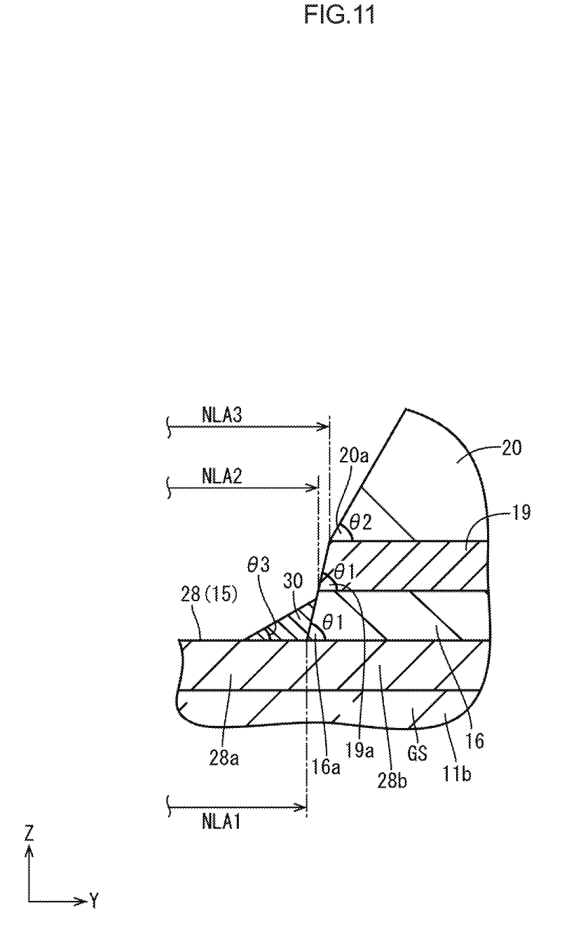

As illustrated in FIGS. 9 and 10, sections of the insulating films 16, 19, 20, 22, and 25 are angled relative to a plate surface of the glass substrate GS to incline from boundaries with the insulating film voided areas (including the insulating film voided areas NLA1 to NLA3). The sections are defined as inclined sections (inclined sections 16a, 19a, and 20a, which will be described later). In this section, only the gate insulating film inclined section 16a (an inclined section, a lower layer-side inclined section) of the gate insulating film 16, the first interlayer insulating film inclined section 19a (an inclined section, an upper layer-side inclined section) of the first interlayer insulating film 19, and a first planarization film inclined section 20a (a second inclined section) of the first planarization film 20 will be described with reference symbols. The inclined sections 16a, 19a, and 20a are disposed at a periphery of the input terminal 28 to overlap an input terminal peripheral section 28b (a terminal peripheral section) having a frame shape for the entire periphery. Angles of slope of the inclined sections 16a, 19a, and 20a relative to the plate surface of the glass substrate GS are acute angles. Specifically, as illustrated in FIG. 11, the angles of slope θ1 of the gate insulating film inclined section 16a and the first interlayer insulating film inclined section 19a are about equal to each other and larger than the angle of slope θ2 of the first planarization film inclined section 20a. The angle of slope θ2 of the first planarization film inclined section 20a is smaller than the angle of slope θ1 of the gate insulating film inclined section 16a and the angle of slope θ1 of the first interlayer insulating film inclined section 19a. A reason why the angle of slope θ1 and the angle of slope θ2 of the inclines sections 16a, 19a, and 20a are different is that the gate insulating film 16 and the first interlayer insulating film 19 having smaller thicknesses are etched using the first planarization film 20 having a larger thickness and being patterned in advance as a mask to pattern the gate insulating film 16 and the first interlayer insulating film 19 (to form the gate insulating film inclined section 16a and the first interlayer insulating film inclined section 19a). The input terminal peripheral section 28b and the inclined sections 16a, 19a, and 20a have vertically-long frame shapes in a plan view with outlines similar to the outline of the input terminal 28.

As described above, the input terminal peripheral section 28b of the input terminal 28 is covered with the insulating films 16, 19, 20, 22, and 25 (the inclined sections 16a, 19a, and 20a) but the input terminal central section 28a of the input terminal 28 is exposed without being covered with the insulating films 16, 19, 20, 22, and 25. The inclined sections 16a, 19a, and 20a of the insulating films 16, 19, 20, 22, and 25 are angled relative to the plate surface of the glass substrate GS. Therefore, the insulating film voided areas NLA1 to NLA3 of the insulating films 16, 19, 20, 22, and 25 are smaller on the lower layer side and larger on the upper layer side.

In the array board 11b according to this embodiment, the inclined sections 16a, 19a, and 20a of the insulating films 16, 19, 20, 22, and 25 are angled as described above. Therefore, condensation may occur in the inclined sections 16a, 19a, and 20a and moisture from the condensation may remain. The angle of slope θ1 of the gate insulating film inclined section 16a of the gate insulating film 16 and the first interlayer insulating film inclined section 19a of the first interlayer insulating film 19 relative to the plate surface of the glass substrate GS is larger in comparison to the first planarization film inclined section 20a of the first planarization film 20. Therefore, the moisture is more likely to remain in an area including the gate insulating film voided area NLA1 and the gate insulating film inclined section 16a and thus the moisture is more likely to remain in the first interlayer insulating film inclined section 19a. The moisture remaining in the gate insulating film inclined section 16a and the first interlayer insulating film inclined section 19a may enter the gate insulating film 16, the first interlayer insulating film 19, an interface between the gate insulating film 16 and the glass substrate GS, an interface between the gate insulating film 16 and the first interlayer insulating film 19, and an interface between the first interlayer insulating film 19 and the first planarization film 20. The entrance of the moisture through the contact holes CH1 and CH2 in the display area AA may cause air bubbles in the liquid crystal layer 11c, which may significantly reduce display quality regarding images displayed in the display area AA.

As illustrated in FIGS. 8 to 10, the array board 11b according to this embodiment includes overlapping portions 30 that are disposed in a layer upper than the gate insulating film 16. Corresponding one of the overlapping portions 30 is disposed to cross a boundary between the gate insulating film voided area NLA1 and the gate insulating film inclined section 16a and to cover at least parts thereof. The overlapping portion 30 overlaps the gate insulating film inclined section 16a and the gate insulating film voided area NLA1 that is adjacent to the gate insulating film inclined section 16a to cross the boundary therebetween. The gate insulating film inclined section 16a is closest to the glass substrate GS among the inclined sections 16a, 19a, and 20a and has the angle of slope θ1 relative to the plate surface of the glass substrate GS larger than the angle of slope θ2 of the first planarization film inclined section 20a. According to the configuration, the area including the boundary between the gate insulating film voided area NLA1 and the gate insulating film inclined section 16a is covered with the overlapping portion 30. Therefore, the moisture is less likely to remain in the area. If the moisture is less likely to remain in the gate insulating film inclined section 16a and therearound, the moisture is less likely to remain in the first interlayer insulating film inclined section 19a disposed in the layer upper than the gate insulating film inclined section 16a and having the same angle of slope θ1. Therefore, the display failure resulting from the retention of the moisture can be reduced and thus display performances of the array board 11b and the liquid crystal panel 11 can be maintained at proper levels.

Specifically, as illustrated in FIGS. 8 to 10, the overlapping portion 30 overlaps a periphery of the gate insulating film voided area NLA1 and most of inner peripheral area of the gate insulating film inclined section 16a (on a gate insulating film voided area NLA1 side). The overlapping portion 30 is disposed to overlap the gate insulating film voided area NLA1 and the gate insulating film inclined section 16a for entire peripheries thereof. The overlapping portion 30 has a vertically-long frame-like two-dimensional shape similar to the two-dimensional shape of the gate insulating film inclined section 16a. As illustrated in FIG. 11, the overlapping portion 30 is angled relative to the plate surface of the glass substrate GS. An angle of slope θ3 is smaller than the angle of slope θ1 of the gate insulating film inclined section 16a. According to the configuration, moisture is less likely to remain in the overlapping portion 30 and therearound. Most of an inner peripheral area of the overlapping portion 30 overlaps the periphery of the gate insulating film voided area NLA1 (the periphery of the input terminal central section 28a of the input terminal 28). The outer peripheral area of the overlapping portion 30 overlaps most of the inner peripheral area of the gate insulating film inclined section 16a (an area excluding the outer peripheral section). The overlapping portion 30 does not overlap the first interlayer insulating film inclined section 19a and the first planarization film inclined section 20a. If the overlapping portion overlaps the entire areas of the first interlayer insulating film inclined section 19a and the first planarization film inclined section 20a in addition to the gate insulating film inclined section 16a, the overlapping portion is less likely to be angled with an angle of slope the same as the angle of slope θ1 and the angle of slope θ2 parallel to the inclined sections 16a, 19a, and 20a. Therefore, moisture is less likely to remain in the overlapping portion 30 and therearound.

As illustrated in FIGS. 9 and 10, the overlapping portion 30 is formed from a section of the second metal film 18 disposed in the layer upper than the gate insulating film 16. If the overlapping portion is formed from any one of the insulating films 16, 19, 20, 22, and 25, the periphery of the input terminal central section 28a of the input terminal 28 covered with the overlapping portion is unable to contact the terminal of the driver 12. Therefore, reliability in connection with the driver 12 may be reduced. By forming the overlapping portion 30 from the section of the second metal film 18 having conductivity, an entire area of the input terminal central section 28a of the input terminal 28 contact the terminal of the driver 12. Therefore, reliability in connection with the driver 12, that is, electrical performance of the input terminal 28 can be maintained.

As described above, the array board 11b (the display board) in this embodiment includes the glass substrate GS (the substrate), the gate insulating film 16 and the first interlayer insulating film 19 (the insulating film), the gate insulating film inclined section 16a and the first interlayer insulating film inclined section 19a (the inclined section), and the overlapping portion 30. The glass substrate GS includes the display area AA in which images can be displayed and the non-display area NAA disposed outside the display area AA to surround the display area AA. The gate insulating film 16 and the first interlayer insulating film 19 include the gate insulating film voided area NLA1 and the interlayer insulating film voided, area NLA2 (the insulating film voided area) which are the holes at least in the non-display area NAA. The gate insulating film inclined section 16a and the first interlayer insulating film inclined section 19a that are the sections of the gate insulating film 16 and the first interlayer insulating film 19 inclined from the boundaries with the gate insulating film voided area NLA1 and the first interlayer insulating film voided area NLA2 and angled relative to the plate surface of the glass substrate GS. The overlapping portion 30 is disposed in the layer upper than the gate insulating film 16 and the first interlayer insulating film 19 to cross the boundary between the gate insulating film voided area NLA1 and the gate insulating film inclined section 16a and the boundary between the first interlayer insulating film voided area NLA2 and the first interlayer insulating film inclined section 19a and to at least overlap them.

The gate insulating film 16 and the first interlayer insulating film 19 are disposed to cross the boundary between the display area AA and the non-display area NAA of the glass substrate GS. The gate insulating film 16 and the first interlayer insulating film 19 include the gate insulating film voided area NLA1 and the first interlayer insulating film voided area NLA2 that are the holes in the non-display area NAA. The gate insulating film voided area NLA1 and the first interlayer insulating film voided area NLA2 in which the gate insulating film 16 and the first interlayer insulating film 19 do not exist are located in the non-display area NAA of the glass substrate GS. Therefore, they are less likely to affect images displayed in the display area AA. The sections of the gate insulating film 16 and the first interlayer insulating film 19 inclined from the boundaries with the gate insulating film voided area NLA1 and with the first interlayer insulating film voided area NLA2 and angled relative to the plate surface of the glass substrate GS are defined as the gate insulating film inclined section 16a and the first interlayer insulating film inclined section 19a. Because the gate insulating film inclined section 16a of the gate insulating film 16 and the first interlayer insulating film inclined section 19a of the first interlayer insulating film 19 are angled as described above, moisture is more likely to remain in the sections and therearound. The display performance of the array board 11b may be reduced due to the moisture. The overlapping portion 30 is disposed in the layer upper than the gate insulating film 16 and the first interlayer insulating film 19 to cross the boundary between the gate insulating film voided area NLA1 and the gate insulating film inclined section 16a and the boundary between the first interlayer insulating film voided area NLA2 and the first interlayer insulating film inclined section 19a and to at least overlap them. Therefore, the moisture is less likely to remain in the gate insulating film inclined section 16a of the gate insulating film 16 and the first interlayer insulating film inclined section 19a of the first interlayer insulating film 19 and therearound. Therefore, the display performance of the array board 11b can be properly maintained.

The overlapping portion 30 is angled relative to the plate surface of the glass substrate GS with the angle of slope θ3 smaller than the angle of slope θ1 of the gate insulating film, inclined section 16a and the first interlayer insulating film inclined section 19a. According to the configuration, the moisture is less likely to remain in the overlapping portion 30 and therearound.

The array board 11b includes the first planarization film 20 (the second, insulating film) and the first planarization film inclined section 20a (the second the inclined section). The first planarization film 20 is disposed in the layer upper than the gate insulating film 16 and the first interlayer insulating film 19. The first planarization film 20 includes the first planarization film voided area NLA3 (the second insulating film voided area) which is the hole in the area overlapping the gate insulating film voided area NLA1, the first interlayer insulating film, voided area NLA2, the gate insulating film inclined section 16a, and the first interlayer insulating film inclined section 19a. The first planarization film, inclined section 20a is the section of the first planarization film 20 inclined from the boundary with the first planarization film, voided area NLA3. The first planarization film inclined section 20a is angled relative to the plate surface of the glass substrate GS with the angle of slope θ2 smaller than the angle of slope θ1 of the gate insulating film inclined section 16a and the first interlayer insulating film inclined section 19a. In the configuration in which the first planarization film 20 is disposed in the layer upper than the gate insulating film 16 and the first interlayer insulating film 19, the angle of slope θ1 of the gate insulating film inclined section 16a and the first interlayer insulating film inclined section 19a formed through the patterning of the gate insulating film 16 and the first interlayer insulating film 19 using the first planarization film 20 as a mask is larger than the angle of slope θ2 of the first planarization film inclined section 20a. According to the configuration, moisture may remain in the gate insulating film inclined section 16a and the first interlayer insulating film inclined section 19a and therearound. Because the overlapping portion 30 overlap the gate insulating film voided area NLA1 and the gate insulating film inclined section 16a to cross the boundary therebetween and the first interlayer insulating film voided area NLA2 and the first interlayer insulating film inclined section 19a to cross the boundary therebetween, the moisture is less likely to remain in the gate insulating film inclined section 16a and the first interlayer insulating film inclined section 19a and therearound.

The overlapping portion 30 is disposed not to overlap the first planarization film inclined section 20a or to cover a part of the first planarization film inclined section 20a. If the overlapping portion is disposed to cover not only the gate insulating film inclined section 16a and the first interlayer insulating film inclined section 19a but also the entire area of the first planarization film inclined section 20a, the overlapping portion is more likely to be parallel to the gate insulating film inclined section 16a, the first interlayer insulating film inclined section 19a, and the first planarization film inclined section 20a. Therefore, moisture is more likely to remain in the overlapping portion and therearound. Because the overlapping portion 30 is disposed not to overlap the first planarization film inclined section 20a or to cover the part of the first planarization film inclined section 20a, the overlapping portion 30 is less likely to be parallel to the gate insulating film inclined section 16a, the first interlayer insulating film inclined section 19a, and the first planarization film inclined section 20a. Therefore, the moisture is less likely to remain in the overlapping portion 30 and therearound.

The array board 11b includes the input terminals 28 (the terminals) formed from the first metal film 15 (the lower layer-side metal film) disposed in the layer lower than the gate insulating film 16 and the first interlayer insulating film 19 in the non-display area NAA. The gate insulating film 16 and the first interlayer insulating film 19 are configured such that the gate insulating film voided area NLA1 and the first interlayer insulating film voided area NLA2 overlap the input terminal central section 28a (the terminal central section) in the middle of the input terminals 28. The gate insulating film inclined section 16a and the first interlayer insulating film inclined section 19a are disposed to overlap the input terminal peripheral section 28b (the terminal peripheral section) at the periphery of each input terminal 28 for the entire periphery. The overlapping portion 30 overlaps the gate insulating film voided area NLA1, the first interlayer insulating film voided area NLA2, the gate insulating film inclined section 16a, and the first interlayer insulating film inclined section 19a for the entire peripheries. The gate insulating film inclined section 16a of the gate insulating film 16 and the first interlayer insulating film inclined section 19a of the first interlayer insulating film 19 configured such that the gate insulating film voided area NLA1 and the first interlayer insulating film voided area NLA2 overlap the input central section 28a of the input terminal 28 are disposed to overlap the input terminal peripheral section 28b of the input terminal 28 for the entire periphery. Because the overlapping portion 30 overlaps the gate insulating film voided area NLA1, the first interlayer insulating film voided area NLA2, the gate insulating film inclined section 16a, and the first interlayer insulating film inclined section 19a for the entire periphery, the moisture is less likely to remain around the gate insulating film inclined section 16a and the first interlayer insulating film inclined section 19a for the entire periphery.

The overlapping portions 30 are formed from the second metal film 18 (the upper layer-side metal film) disposed in the layer upper than the gate insulating film 16 and the first interlayer insulating film 19 in the non-display area NAA. With the overlapping portions 30 formed from the second metal film 18, the electrical performances of the input terminals 28 can be maintained.

The array board 11b includes the driver 12 (the display driver) mounted in the non-display area NAA and connected to the input terminals 28. Although the input terminals 28 connected to the driver 12 are exposed to the outside before the driver 12 is mounted, moisture is less likely to remain in the gate insulating film inclined section 16a of the gate insulating film 16 and the first interlayer insulating film inclined section 19a of the first interlayer insulating film 19 and therearound close to the input terminals 28.

The liquid crystal panel 11 (the display device) in this embodiment includes the array board 11b described above and the CF board 11a (the common board) disposed opposite the array board 11b. Because the display failure due to the retention of moisture is less likely to occur in the array board 11b, the liquid crystal panel 11 has high display reliability.

### Second Embodiment

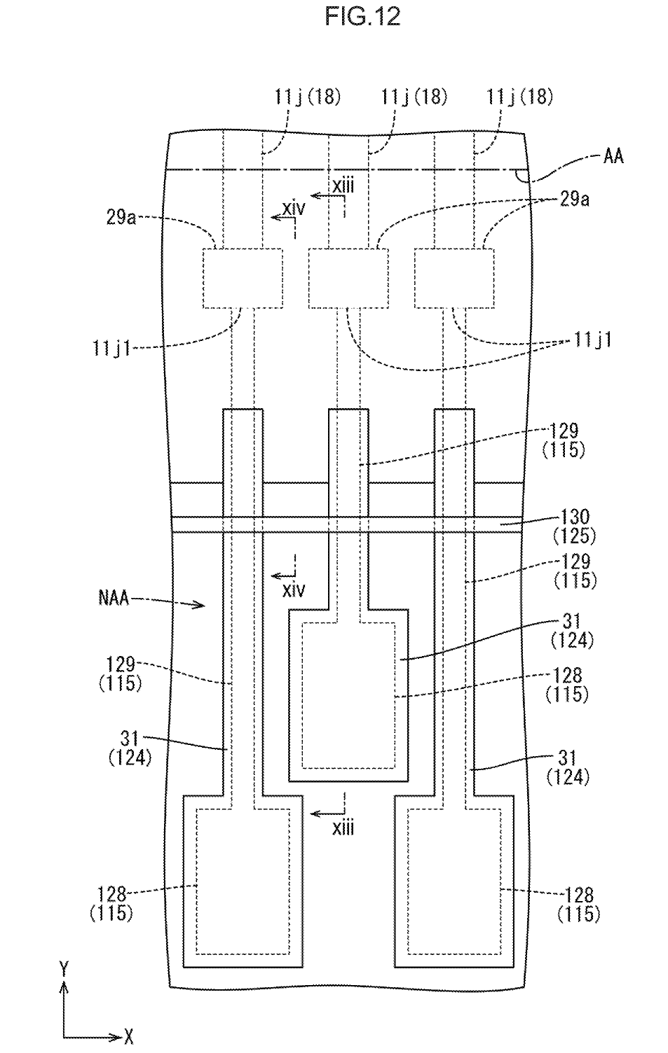

A second embodiment of the present invention will be described with reference to FIGS. 12 to 14. The second embodiment includes insulating films 116, 119, 120, 122, and 125 and overlapping portions 130 having configurations different from those of the first embodiment. Configurations, functions, and effects similar to those of the first embodiment will not be described.

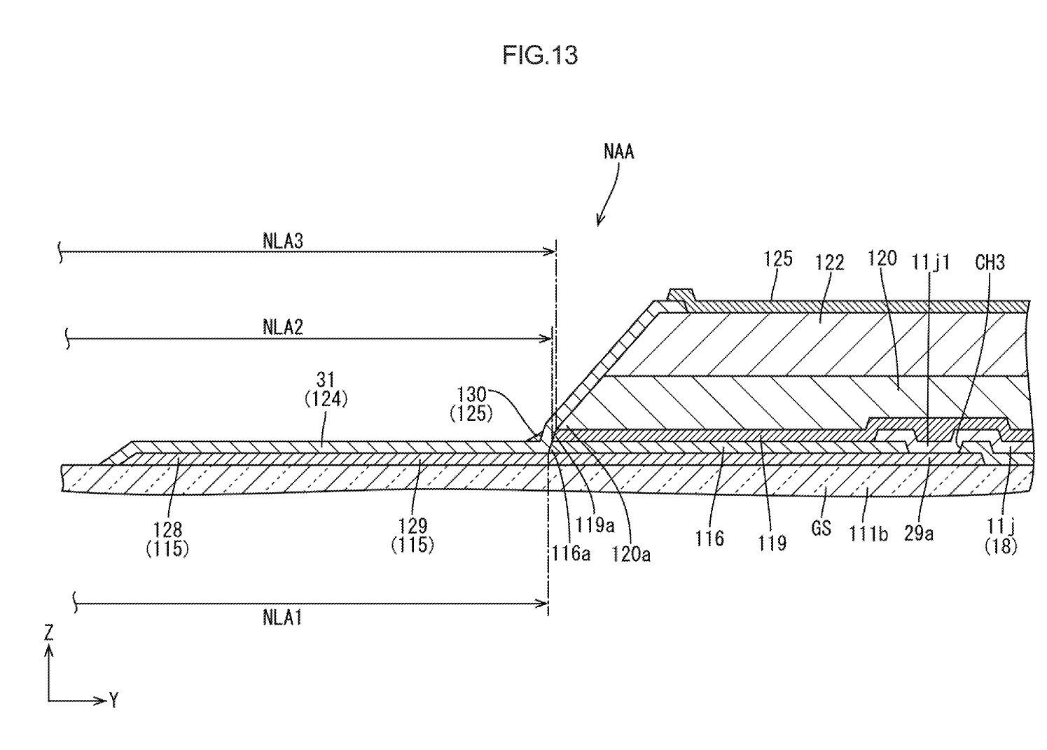

As illustrated in FIG. 12, an array board 111b according to this embodiment includes the insulating films 116, 119, 120, 122, and 125 that include sections overlapping a mounting area in the non-display area in which a driver and a flexible board are mounted. The sections are collectively removed to form holes. Insulating film voided areas NLA1 to NLA3 include not only areas overlapping the each terminal (including an input terminal 128) in the non-display area NAA but also areas overlapping areas outside the terminals including areas between the terminals. The insulating films 116, 119, 120, 122, and 125 are configured such that the insulating film voided areas NLA1 to NLA3 cross the input terminals 128 arranged along the plate surface of the glass substrate GS to overlap the input terminals 128. The input terminals 128 are exposed without being entirely covered with the insulating films 116, 119, 120, 122, and 125. Terminal lines 129 connected to the input terminals 128 include sections that overlap the insulating film voided areas NLA1 to NLA3 and are not covered with the insulating films 116, 119, 120, 122, and 125. As illustrated in FIGS. 12 and 13, sections of terminal lines 120 overlapping the insulating film voided areas NLA1 to NLA3 are covered with a protective portion 31. The protective portion 31 is formed from a first transparent electrode film 124 that also forms a common electrode (see FIGS. 9 and 10). The protective portion 31 covers not only the terminal lines 129 but also the input terminals 128. During wet-etching of the first transparent electrode film 124 that is formed and exposed in a production of the array board 111b, aluminum layers in a part of each terminal line 129 and each input terminal 128 formed from a third metal film 121 having a three-layer structure is more likely to be etched by an etching solution in comparison to titanium layers. Therefore, the aluminum layers of the part of the terminal line 129 and the input terminal 128 may be narrower than the titanium layers, that is, side-shift defects may be produced. Because the part of each terminal line 129 and each input terminal 128 are covered with the protective portion 31 as described above, the part of each terminal line 129 and each input terminal 128 are protected by the protective portion 31 from the etching solution during the wet-etching. Therefore, the side-shift defects are less likely to occur in the terminal lines 129 and the input terminals 128.

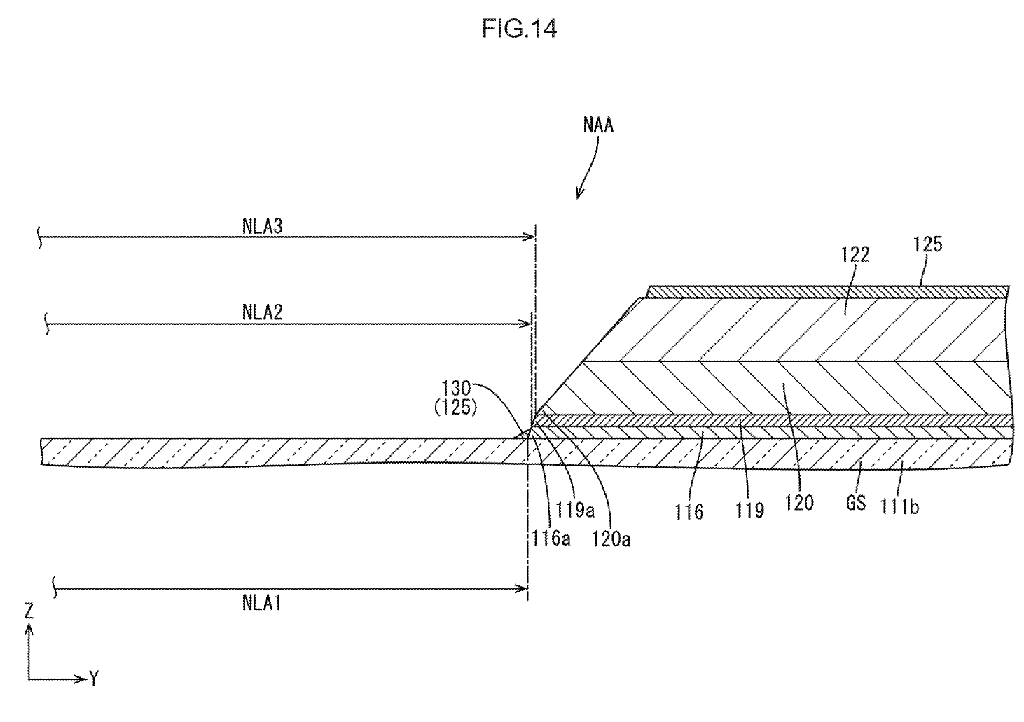

As illustrated in FIGS. 12 to 14, inclined sections 116a, 119a, and 120a are disposed to cross the terminal lines 129 that are arranged along the X-axis direction. The inclined sections 116a, 119a, and 120a are linearly arranged along the X-axis direction in a plan view. The terminal lines 129 and the protective portion 31 are disposed over areas of the inclined sections 116a, 119a, and 120a overlapping the terminal lines 129 (FIG. 13). The terminal lines 129 and the protective portion 31 are not disposed over areas of the inclined sections 116a, 119a, and 120a not overlapping the terminal lines 129 (FIG. 14). The overlapping portion 130 is formed from a part of the second interlayer insulating film 125 (the second insulating film) disposed in a layer upper than a gate insulating film 116 and a first interlayer insulating film 119 and disposed to cross the terminal lines 129. Although the overlapping portion 130 crosses the terminal lines 129, the over lapping portion 130 does not develop a short circuit between the adjacent terminal lines 129 because the overlapping portion is formed from the part of the second interlayer insulating film 125. The overlapping portion 130 linearly extends along the X-axis direction in the plan view along the inclined sections 116a, 119a, and 120a. The overlapping portion 130 includes sections that overlap the terminal lines 129 and sections that do not overlap the terminal lines 129. The sections of the overlapping portion 130 overlapping the terminal lines 129 are disposed over the protective portion 31 (FIG. 13). The sections of the overlapping portion 130 not overlapping the terminal lines 129 are disposed over a gate insulating film inclined section 116a (FIG. 14). In a section of the array board 111b not overlapping the terminal lines 129, an area including the boundary between the gate insulating film voided area NLA and the gate insulating film inclined section 116a and therearound is covered with the overlapping portion 130. Therefore, moisture is less likely to remain in the area. In a section of the array board 111b overlapping the terminal lines 129, an area of the protective portion 31 inclined along the gate insulating film inclined section 116a and the first interlayer insulating film 119a and therearound is covered with the overlapping portion 130. Therefore, moisture is less likely to remain in the area and therearound.

As described above, this embodiment includes the input terminals 128, the terminal lines 129, and the second interlayer insulating film 125 (The second insulating film). The input terminals 128 are formed from a first metal film 115 that is disposed in the layer lower than the gate insulating film 116 and the first inter layer insulating film 119 in the non-display area NAA. The terminal lines 129 are formed from the first metal film 115 and connected to the input terminals 128 at least in the non-display area NAA. The second interlayer insulating film 125 is disposed in the layer upper than the gate insulating film 116 and the first interlayer insulating film 119. The gate insulating film 116 and the first interlayer insulating film 119 are configured such that the gate insulating film voided area NLA1 and the first interlayer insulating film voided area NLA2 cross and overlap the input terminals 128. The gate insulating film inclined section 116a and the first interlayer insulating film inclined section 119a are disposed to cross the terminal lines 129. The overlapping portion 130 is formed from the part of the second interlayer insulating film 125 and disposed to cross the terminal lines 129. The gate insulating film inclined section 116a and the first interlayer insulating film inclined section 119a of the gate insulating film 116 and the first interlayer insulating film 119 that are configured such that the gate insulating film voided area NLA1 and the first interlayer insulating film voided area NLA2 cross and overlap the input terminals 128. The overlapping portion 130 is formed from the part of the second interlayer insulating film 125 that is disposed in the layer upper than the gate insulating film 116 and the first interlayer insulating film 119 and disposed to cross the terminal lines 129. Therefore, moisture is less likely to remain in the gate insulating film inclined section 116a and the first interlayer insulating film inclined section 119a and therearound without developing the short circuit between the adjacent terminal lines 129.

### Third Embodiment

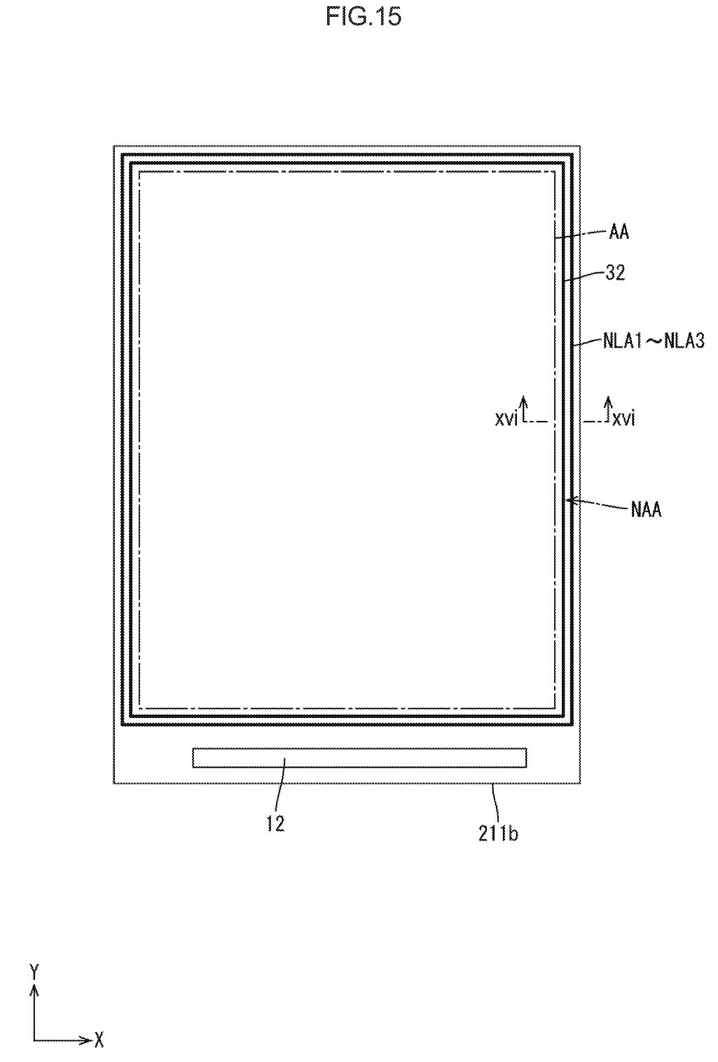

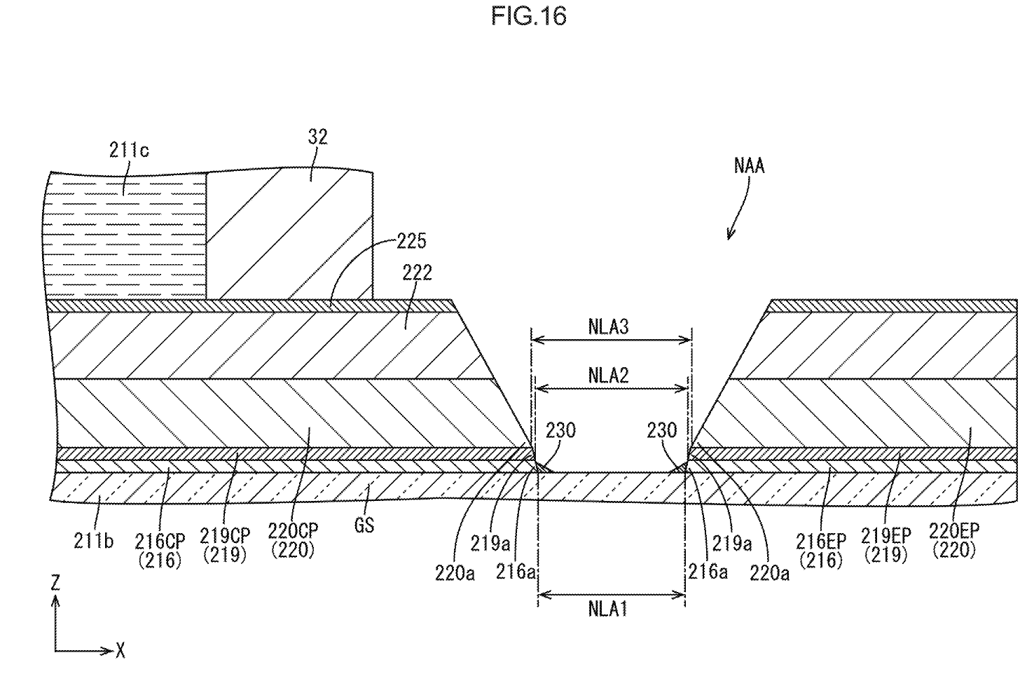

A third embodiment of the present invention will be described with reference to FIGS. 15 and 16. The third embodiment includes insulating films 216, 219, 220, 222, and 225 and overlapping portions 230 having configurations different from the first embodiment. Configurations, functions, and effects similar to those of the first and the second embodiments will not be described.

As illustrated in FIGS. 15 and 16, the array board 211b according to this embodiment includes holes formed by removing frame shaped areas of the insulating films 216, 219, 220, 222, and 225 in the non-display area NAA surrounding the display area AA. The holes are defined as insulating film voided areas (including the insulating film, voided areas NLA1 to NLA3). The insulating film voided areas formed in the insulating films 216, 219, 220, 222, and 225 have vertically-long frame-like two-dimensional shapes similar to the display area AA. The insulating film voided areas divide the insulating films 216, 219, 220, 222, and 225 into central portions (including insulating film central portions 216CP, 219CP, and 220CP) and peripheral portions (including insulating film peripheral portions 216EP, 219EP, and 220EP). The insulating film voided areas are located outer than (on an opposite side from the display area AA) a sealing member 32 that seals a liquid crystal layer 211c to surround the sealing member 32 for an entire periphery. Namely, the sealing member 32 is disposed on the insulating film central portion. According the configuration, even if moisture enters the insulating film peripheral portions from the outside, the moisture is less likely to enter the insulating film central portions because the insulating film central portions are separated from the insulating film peripheral portions by the insulating film voided areas formed in the frame shape to surround the display area AA. Because the sealing member 32 that seals the liquid crystal layer 211c is disposed on the insulating film central portion, the entrance of the moisture to the insulating film central portions is restricted. Therefore, formation of air bubbles in the liquid crystal layer 211c can be effectively reduced. In this embodiment, only the gate insulating film central portion CP and gate insulating film peripheral portion 216EP of the gate insulating film 216, the first interlayer insulating film central portion 219CP and the first interlayer insulating film peripheral portion 219EP of a first interlayer insulating film 219, and the first planarization film central portion 220CP and the first planarization film peripheral portion 220EP of a first planarization film 220 will be described with reference symbols.

The insulating film central portions 216CP, 219CP, and 220CP and the insulating film peripheral portions 216EP, 219EP, and 220EP include inclined sections 216a, 219a, and 220a disposed for entire peripheries thereof. The inclined sections 216a, 219a, and 220a of the insulating film central portions 216CP, 219CP, and 220CP on the inner peripheral side are inclined inward from the boundary with the insulating film voided areas NLA1 to NLA3 and angled relative to the plate surface of the glass substrate GS. The inclined sections 216a, 219a, and 220a of the insulating film peripheral portions 216EP, 219EP, and 220EP on the outer peripheral side are inclined outward from the boundary with the insulating film voided areas NLA1 to NLA3 and angled relative to the plate surface of the glass substrate GS. The inclined sections 216a, 219a, and 220a have vertically-long frame shapes in a plan view similar to the display area AA. The overlapping portions 230 are disposed to overlap the insulating film voided areas NLA1 to NLA3 and the inclined sections 216a, 219a, and 220a for the entire peripheries. The overlapping portion 230 on the inner side is disposed to overlap the insulating film voided areas NLA1 to NLA3 and the inclined sections 216a, 219a, and 220a on the inner side to cross boundaries therebetween. The overlapping portion 230 on the outer side is disposed to overlap the insulating film voided areas NLA1 to NLA3 and the inclined sections 216a, 219a, and 220a on the outer side to cross boundaries therebetween. According to the configuration, moisture is less likely to remain in the gate insulating film inclined sections 216a of the gate insulating film central portion 216CP and the gate insulating film peripheral portion 216EP disposed for the entire peripheries because of the overlapping portions 230. Therefore, the entrance of moisture into the gate insulating film, central portion 216CP can be further properly reduced.

As described above, in this embodiment, the gate insulating film voided area NLA1 of the gate insulating film 216 and the first interlayer insulating film voided area NLA2 of the first interlayer insulating film 219 are formed in the frame shapes to surround the display area AA. The gate insulating film central portion CP and the first interlayer insulating film central portion 219CP (the insulating film central portion) are separated from the gate insulating film peripheral portion 216EP and the first interlayer insulating film peripheral portion 219EP (the insulating film peripheral portion.) by the gate insulating film voided area NLA1 and the first interlayer insulating film voided area NLA2. Gate insulating film inclined sections 216a and the first interlayer insulating film inclined sections 219a are disposed at the gate insulating film central portion 216CP, the first insulating film central portion 219CP, the gate insulating film peripheral section 216EP, and the first interlayer insulating film peripheral section 219EP for the entire peripheries. The overlapping portions 230 overlap the gate insulating film voided area NLA1, the first interlayer insulating film voided area NLA2, the gate insulating film inclined sections 216a, and the first interlayer insulating film inclined sections 219a for the entire peripheries. According to the configuration, even if moisture from the outside enters the gate insulating film peripheral portion 216EP and the first interlayer insulating film peripheral portion 219EP, the moisture in the gate insulating film peripheral portion 216EP and the first interlayer insulating film peripheral portion 219EP is less likely to enter the gate insulating film central portion 216CP and the first interlayer insulating film central portion 219CP because the gate insulating film central portion 216CP and the first interlayer insulating film central portion 219CP are separated from the gate insulating film peripheral portion 216EP and the first insulating film peripheral portion 219EP by the gate insulating film voided area NLA1 and the first interlayer insulating film voided area NLA2 formed in the frame shapes to surround the display area AA. Because of the overlapping portions 230, moisture is less likely to remain in the gate insulating film inclined sections 216a and the first interlayer insulating film inclined sections 219a of the gate insulating film central portion 216CP, the first interlayer insulating film central portion 219CP, the gate insulating film peripheral portion 216EP, and the first interlayer insulating film peripheral portion 219EP disposed for the entire peripheries. Therefore, the entrance of moisture into the gate insulating film central portion 216CP and the first interlayer insulating film central portion 219CP can be further properly reduced.

### Fourth Embodiment

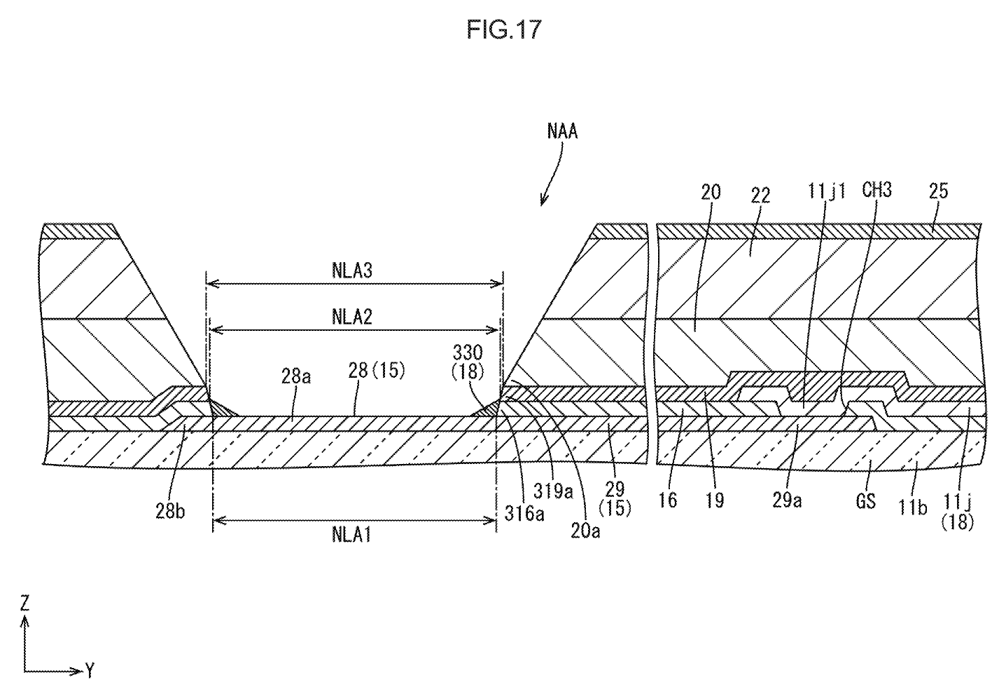

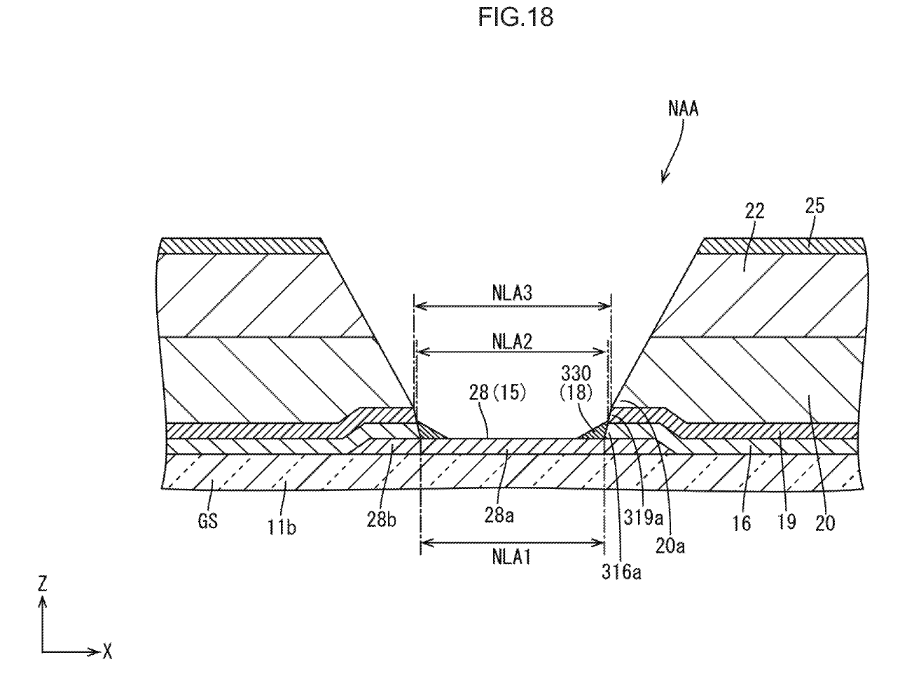

A fourth embodiment will be described with reference to FIGS. 17 and 18. The fourth embodiment includes overlapping portions 330 formed in areas different from the first embodiment. Configurations, functions, and effects similar to those of the first embodiment will not be described.

As illustrated in FIGS. 17 and 18, the overlapping portions 330 in this embodiment are disposed to cover not only entire areas of gate insulating film inclined sections 316a but also parts of first interlayer insulating film inclined sections 319a (on gate insulating film voided area NLA1 sides). According to the configuration, moisture is less likely to remain in areas between outer peripheral edges of the gate insulating film voided area NLA1 and the parts of the first interlayer insulating film inclined sections 319a with the gate insulating film inclined sections 316a therebetween because of the overlapping portions 330.

### Other Embodiments

The present invention is not limited to the above embodiments described in the above sections and the drawings. For example, the following embodiments may be included in technical scopes of the present invention.

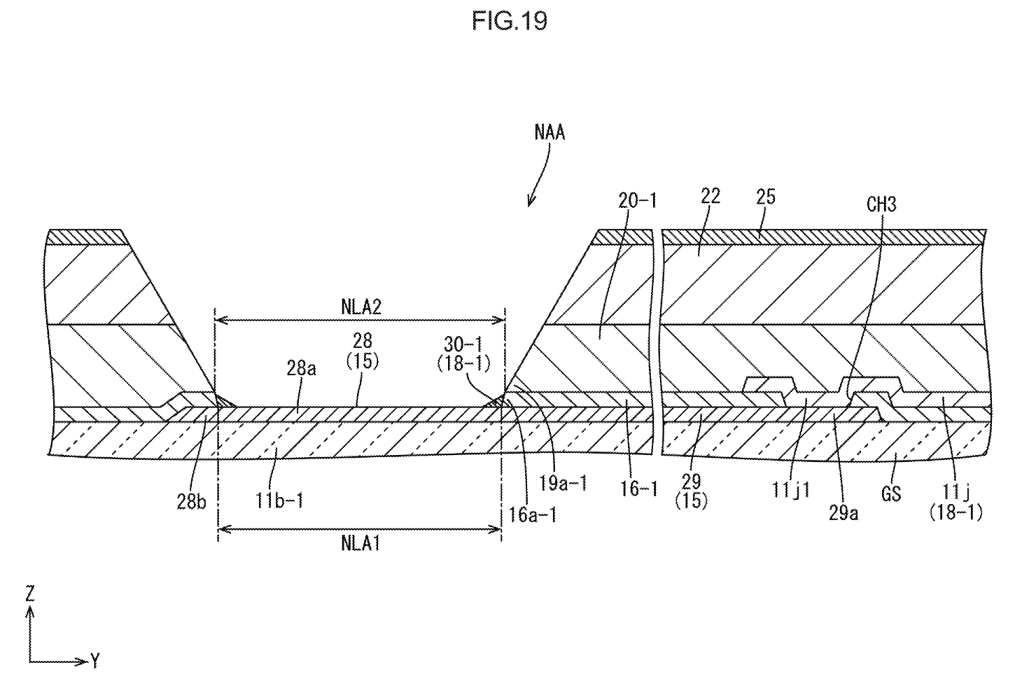

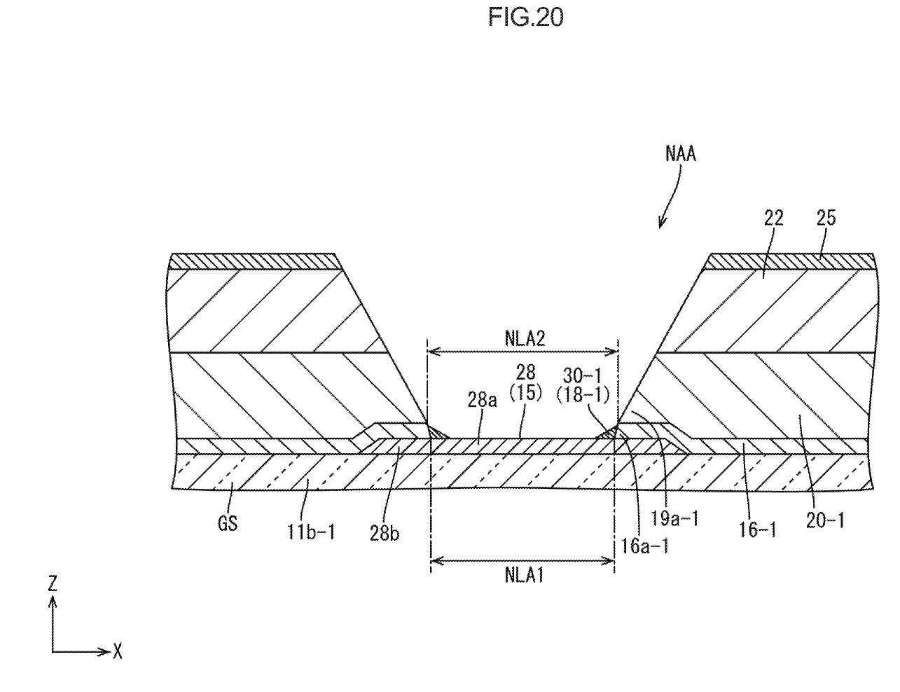

(1) As a modification of the first embodiment, the first interlayer insulating film may be omitted. As illustrated in FIGS. 19 and 20, an array board 11b-1 in the modification includes gate insulating film 16-1, a second metal film 18-1, and a first planarization film 20-1 that is disposed over the gate insulating film 16-1 and the second metal film 18-1. Overlapping portions 30-1 cover parts of gate insulating film inclined sections 16a-1 but not overlap first planarization film inclined sections 20a-1 in a layer upper than the gate insulating film inclined sections 16a-1.

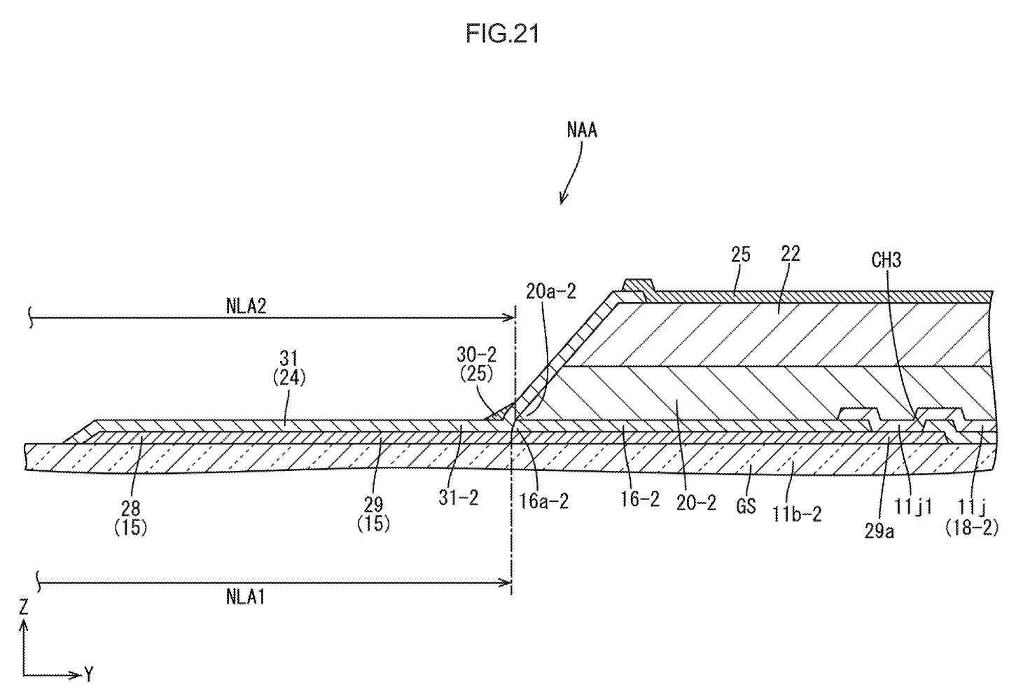

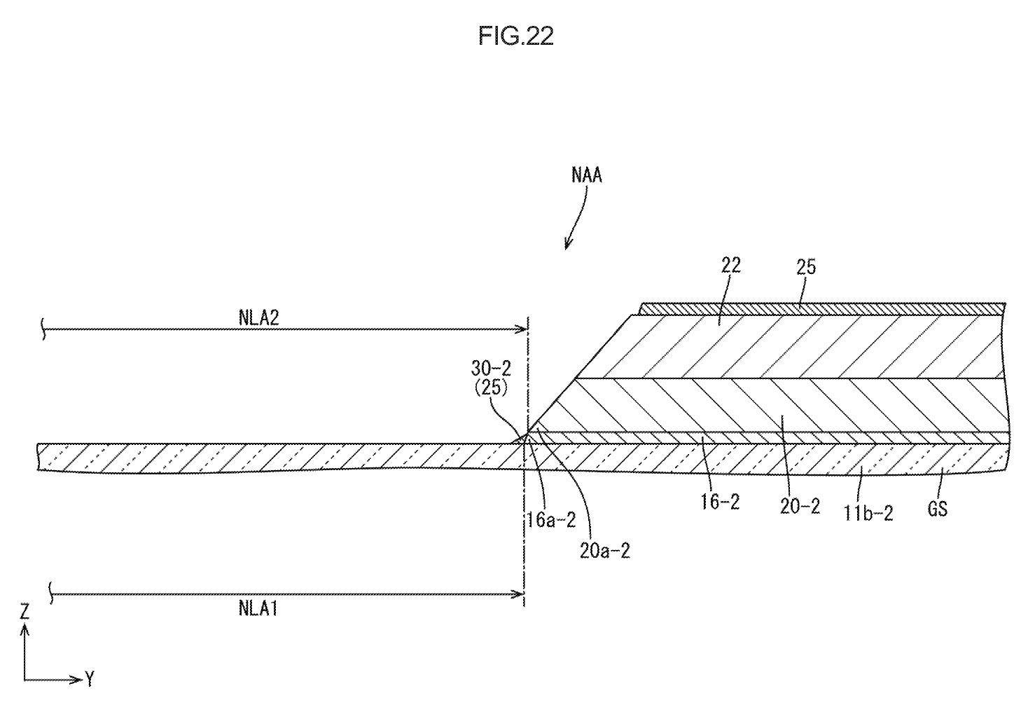

(2) As a modification of the second embodiment, the first interlayer insulating film may be omitted. As illustrated in FIGS. 21 and 22, an array board 11b-2 in the modification includes gate insulating film 16-2, a second metal film 18-2, and a first planarization film 20-2 that is disposed over the gate insulating film 16-2 and the second metal film 18-2. Overlapping portions 30-2 cover a part of a protective portion 31-2 and a part of gate insulating film inclined sections 16a-2 but not overlap first planarization film inclined sections 20a-2.

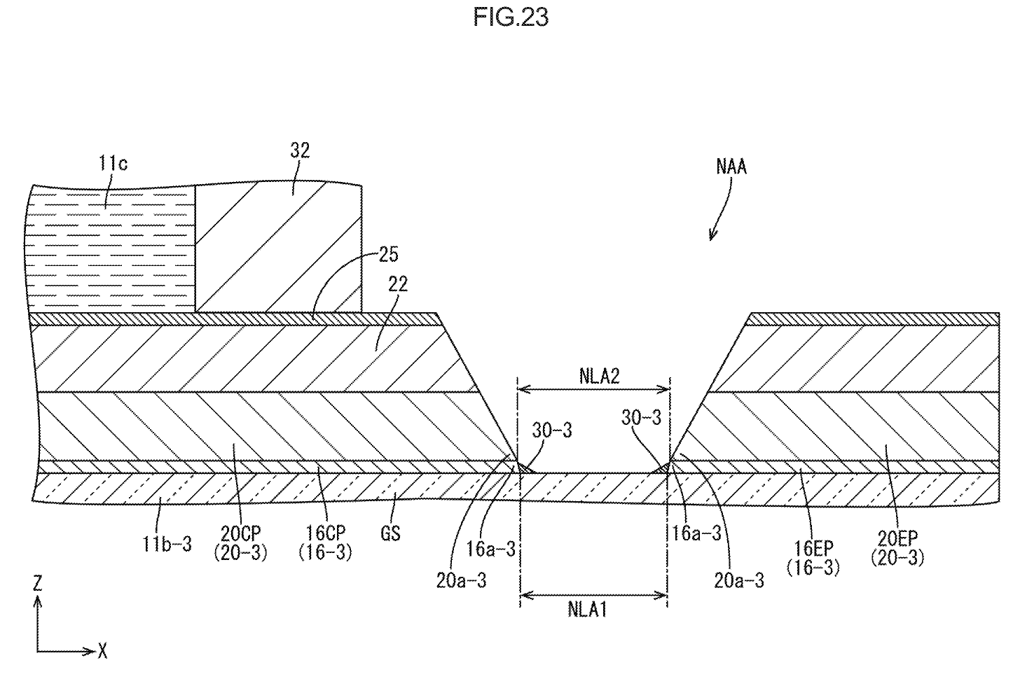

(3) As a modification of the third embodiment, the first interlayer insulating film may be omitted. As illustrated in FIG. 23, an array board 11b-3 in the modification includes gate insulating film 16-3 and a first planarization film 20-3 that is disposed over the gate insulating film 16-3. Overlapping portions 30-3 cover parts of gate insulating film inclined sections 16a-3 but not overlap first planarization film inclined sections 20a-3 in a layer upper than the gate insulating film inclined sections 16a-3.

(4) In each of the above embodiments (except for the second embodiment), the overlapping portions are formed from the second metal film. However, the overlapping portions may be formed from the third metal film or the fourth metal film. Alternatively, the overlapping portions may be formed from the first transparent electrode film or the second transparent electrode film.

(5) In the second embodiment, the overlapping portions are formed from the second interlayer insulating film. However, the overlapping portions may be formed from other insulating films such as the second planarization film.

(6) In each of the above embodiments, the overlapping portions include the cross-sectional surfaces that are angled relative to the plate surface of the glass substrate. However, the cross-sectional surfaces of the overlapping portions may be curved surfaces such as arched surfaces.

(7) In each of the above embodiments, the overlapping portions cover only the parts of the gate insulating film inclined sections (the boundaries with the gate insulating film voided area and therearound). However, the parts of the gate insulating film inclined sections covered with the overlapping portions may be altered where appropriate. For example, the overlapping portions may cover the entire areas of the gate insulating film inclined sections.

(8) In the fourth embodiment, the overlapping portions cover the entire areas of the gate insulating film inclined sections and the parts of the first interlayer insulating film inclined sections. However, the overlapping portions may be configured to cover the entire areas of the gate insulating film inclined sections and the entire areas of the first interlayer insulating film inclined sections.

(9) In the fourth embodiment, the overlapping portions overlap not only the gate insulating film inclined sections but also the first interlayer insulating film inclined sections. However, the overlapping sections may be configured to cover parts of the first planarization film inclined sections (the boundaries with the first planarization film voided area) in addition to the gate insulating film inclined sections and the first interlayer insulating sections. The overlapping portions may be configured to cover the entire areas of the first planarization film inclined sections in addition to the gate insulating film inclined sections and the first interlayer insulating film inclined sections. The overlapping portions may be configured to cover parts of the second planarization film inclined sections in addition to the gate insulating film inclined sections, the first interlayer insulating film inclined sections, and the first planarization film inclined sections.

(10) In each of the above embodiments, the overlapping portions selectively overlap the periphery of the gate insulating film voided area. However, the sections of the gate insulating film voided area covered with the overlapping portions may be altered where appropriate. For example, the overlapping portions may be configured to entirely cover the gate insulating film voided area. In this case, it is preferable that the overlapping portions are formed from the conductive film having conductivity (the metal film or the transparent electrode film).

(11) In each of the above embodiments, the terminal lines are formed from the first metal film that also forms the gate lines. However, the terminal lines may be formed from the second metal film that also forms the source lines, from the third metal film that also forms the TFT connecting portions, or from the fourth metal film that also forms the position detection lines. If the terminal lines are formed from the metal film that is different from the metal film of the input terminals, the terminal lines may be connected with the input terminals via contact holes formed in the insulating film between the terminal lines and the input terminals.

(12) In each of the above embodiments, the input terminals are formed from the first metal film that also forms the gate lines. However, the input terminals may be formed from the second metal film that also forms the source lines, from the third metal film that also forms the TFT connecting portions, or from the fourth metal film that also forms the position detection lines. If the input terminals are formed from the metal film that is different from the metal film of the terminal lines, the input terminals may be connected with the terminal lines via contact holes formed in the insulating film between the terminal lines and the input terminals.

(13) In each of the above embodiments, the terminal lines are connected to the source lines. However, the terminal lines may be connected to the lines other than the source lines such as the gate lines and the position detection lines.

(14) In each of the above embodiments, the position input is performed by the finger of the user. However, the position input may be performed by a position input device other than the finger such as a stylus.

(15) In each of the above embodiments, the position detection electrodes and the common electrode are unified. However, the position detection electrode may be provided separately from the common electrode.

(16) In each of the above embodiment sections, the in-cell type liquid crystal panel including the touchscreen pattern (e.g., the position detection electrodes and the position detection lines) is embedded in the liquid crystal panel is described. However, the liquid crystal panel may be an on-cell type display panel or an out-cell type display panel. Specifically, the out-cell type liquid crystal panel may not have the position detection function (the touchscreen pattern).

(17) In each of the above embodiment sections, the liquid crystal display device having the position detection function (the touchscreen pattern). However, the present invention may be applied to liquid crystal display devices that do not have the position detection function.

(18) In each of the above embodiments, the liquid crystal panel has the rectangular shape in the plan view. However, the present invention may be applied to liquid crystal panels having quadrilateral shapes, circular shapes, and overall shapes in the plan view.

(19) In each of the above embodiments, the driver is COG-mounted on the array board of the liquid crystal panel. However, the driver may be chip-on-film (COF) mounted on the liquid crystal panel flexible circuit board.

(20) In each of the above embodiments, the semiconductor film of the channels of the TFT is made of the oxide semiconductor material. Other than that, continuous grain (CG) silicon, which is one kind of polysilicon, or amorphous silicon may be used as a material for the semiconductor film.

(21) In each of the above embodiment sections, the liquid crystal panel that is configured to operate in FFS mode is described. However, the present invention may be applied to liquid crystal panels that are configured to operate in other modes such as in-plane switching (IPS) mode and vertical alignment (VA) mode.

(22) In each of the above embodiment sections, the color filters of the liquid crystal panel have the three-color configuration of red, green, and blue. However, the present invention may be applied to color filters have a four-color configuration including yellow color portions in addition to the red, the green, and the blue color portions.

(23) In each of the above embodiment sections, the liquid crystal panel that includes the liquid crystal layer that is sandwiched between the boards is described. However, the present invention may be applied to a display panel that includes functional organic molecules other than the liquid crystals sandwiched between boards.

(24) In each of the above embodiments, the TFTs are used as the switching components of the liquid crystal panel. However, the present invention may be applied to a liquid crystal panel that includes switching components other than TFTs (e.g., thin film diodes (TFD)). The present invention may be applied to a liquid crystal panel that is configured to display black-and-white images other than the liquid crystal panel that is configured to display color images and a method of producing the liquid crystal panel.

(25) In each of the above embodiment sections, the liquid crystal panel is described. However, the present invention may be applied to other types of display panels (e.g., plasma display panels (PDPs), organic EL panels, electrophoretic display panels (EPDs), and micro electro mechanical systems (MEMS)).

### EXPLANATION OF SYMBOLS

11: Liquid crystal panel (Display panel)

11a: CF board (Common board)

11b, 11b-1, 11b-2, 11b-3, 111b, 211b: Array board (Display board)

12: Driver (Display driver)

15, 115: First metal film (Lower layer-side metal film)

16, 16-1, 16-2, 16-3, 116, 216: Gate insulating film (Insulating film)

16a, 16a-1, 16a-2, 16a-3, 116a, 216a, 316a: Gate insulating film inclined section (Inclined section)

18, 18-1, 18-2: Second metal film (Upper layer-side metal film)

19, 119, 219: First interlayer insulating film (Insulating film)

19a, 119a, 219a, 319a: First interlayer insulating film inclined section (Inclined section)

20, 20-1, 20-2, 20-3, 120, 220: First planarization film (Second insulating film)

20a, 20a-1, 20a-2, 20a-3, 120a, 220a: First planarization film inclined section (Second inclined section)

25, 125, 225: Second interlayer insulating film (Second insulating film)

28, 128: Input terminal (terminal)

28a: Input terminal central section (Terminal central section)

28b: Input terminal peripheral section (Terminal peripheral section)

29, 129: Terminal line

30, 30-1, 30-2, 30-3, 130, 230, 330: Overlapping portion

216CP: Gate insulating film central portion (Insulating film central portion)

216EP: Gate insulating film peripheral portion (Insulating film peripheral portion)

AA: Display area

NAA: Non-display area

NLA1: Gate insulating film voided area (Insulating film voided area)

NLA2: First interlayer insulating film voided area (Insulating film voided area)

NLA3: First planarization film voided area (Second insulating film non-disposes area)

1. A display board comprising:
a board including a display area in which an image can be displayed and a non-display area disposed outside the display area to surround the display area;
an insulating film disposed to cross a boundary between the display area and the non-display area and including a hole at least in the non-display area, the hole being defined as an insulating film voided area;
at least one inclined section inclined from a boundary with the insulating film voided area and angled relative to a plate surface of the board, the at least one inclined section being a section of the insulating film; and
an overlapping portion disposed in a layer upper than the insulating film to overlap the insulating film voided area and the at least one inclined section to cross the boundary between the insulating film voided area and the at least one inclined section.

2. The display board according to claim 1, wherein the overlapping portion is angled relative to the plate surface of the board with an angle of slope smaller than an angle of slope of the at least one inclined section.

3. The display board according to claim 1, further comprising:
a second insulating film disposed in a layer upper than the insulating film and including a hole in an area overlapping the insulating film voided area and the at least one inclined section, the hole being defined as a second insulating film voided area; and
a second inclined section inclined from a boundary with the second insulating film voided area and angled relative to the plate surface of the board with an angle of slope smaller than the angle of slope of the at least one inclined section.

4. The display board according to claim 3, wherein the overlapping portion is disposed not to overlap the second inclined section or to cover a part of the second inclined section.

5. The display board according to claim 1, further comprising a terminal formed from a lower layer-side metal film disposed in a layer lower than the insulating film in the non-display area, wherein
the insulating film is configured such that the insulating film voided area overlaps a terminal central section of the terminal,
the at least one inclined section is disposed to overlap a terminal peripheral section of the terminal for an entire periphery of the terminal peripheral section, and
the overlapping portion overlaps the insulating film voided area and the at least one inclined section for entire peripheries of the insulating film voided area and the at least one inclined section.

6. The display board according to claim 5, wherein the overlapping portion is made from an upper-layer metal film disposed in a layer upper than the insulating film in the non-display area.

7. The display board according to claim 1, further comprising:
a plurality of terminals formed from a lower layer-side metal film disposed in a layer lower than the insulating film in the non-display area;
a plurality of terminal lines formed from the lower layer-side metal film and connected to the plurality of terminals in the non-display area; and
a second insulating film disposed in a layer upper than the insulating film, wherein the insulating film is configured such that the insulating film voided area overlaps the plurality of terminals to cross the plurality of terminals,
the at least one inclined section is disposed to cross the plurality of terminal lines, and
the overlapping portion is formed from a section of the second insulating film and disposed to cross the plurality of terminal lines.

8. The display board according to claim 5, further comprising a display driver mounted in the non-display area and connected to the terminal.

9. The display board according to claim 1, wherein
the insulating film includes an insulating film central portion and an insulating film peripheral portion separated from each other by the insulating film voided area formed in a frame shape to surround the display area, and
the at least one inclined section includes an inclined section at the insulating film central portion extending for an entire periphery of the insulating film central portion and an inclined section at the insula ting film peripheral portion extending for an entire periphery of the insulating film peripheral portion, and
the overlapping portion overlaps the insulating film voided area and the at least one inclined section.

10. A display device comprising:
the display board according to claim 1; and
a common board disposed opposite the display board.
